(19) United States
(12) Patent Application Publication
(10) Pub. No.: US 2026/0223458 A1
(43) Pub. Date: Jul. 30, 2026

(54) DISPLAY PANEL AND DISPLAY DEVICE

(71) Applicant: WUHAN TIANMA MICROELECTRONICS CO., LTD., Wuhan (CN)

(72) Inventor: Fei LI, Wuhan (CN)

(73) Assignee: WUHAN TIANMA MICROELECTRONICS CO., LTD., Wuhan (CN)

(21) Appl. No.: 19/145,198

(22) PCT Filed: May 28, 2024
(86) PCT No.: PCT/CN2024/095710

§ 371 Date: Jul. 2, 2025

(30) Foreign Application Priority Data
Aug. 31, 2023 (CN) 202311131077.8

(51) Int. Cl. H10D 86/40; H10D 86/60

(52) U.S. Cl. CPC H10D 86/441; H10D 86/60

(57) ABSTRACT

A display panel and a display device. The display panel comprises pixel circuits and signal lines. Each pixel circuit comprises a driving transistor, a bias transistor, and a gate initialization transistor; each signal line comprises a bias signal line and a first reference signal line; the bias transistor is electrically connected between at least one of a first electrode and a second electrode of the driving transistor and the bias signal line; and the gate initialization transistor is electrically connected between a gate of the driving transistor and the first reference signal line.

The present application is the national phase application of International Patent Application No. PCT/CN2024/095710, titled “DISPLAY PANEL AND DISPLAY DEVICE”, filed on May 28, 2024, which claims priority to Chinese Patent Application No. 202311131077.8, titled “DISPLAY PANEL AND DISPLAY DEVICE”, filed on Aug. 31, 2023 with the China National Intellectual Property Administration, both of which are incorporated herein by reference in their entireties.

### FIELD

The present disclosure relates to the field of display technology, and in particular to a display panel and a display device.

### BACKGROUND

With the advancement of display technology, the demand for a display panel with low frequency and low power consumption is becoming increasingly urgent. Such display panel is required to be provided with a signal line for transmitting a signal to a pixel circuit with low power consumption and high transmission stability. Therefore, how to provide a new display panel that can reduce the power consumption of the signal line for transmitting the signal to the pixel circuit while ensuring the stability of signal transmission to meet the requirements of low frequency and low power consumption is an urgent issue to be addressed in the art.

### SUMMARY

In order to address the above issue, a display panel and a display device are provided according to embodiments of the present disclosure, to reduce the power consumption of the signal line for transmitting the signal to the pixel circuit while ensuring the stability of signal transmission to meet the requirements of low frequency and low power consumption.

In order to achieve the above objectives, the following solutions are provided according to the embodiments of the present disclosure.

In one embodiment, a display panel is provided according to an embodiment of the present disclosure. The display panel includes a substrate, a pixel circuit and a signal line that are arranged on a side of the substrate. The pixel circuit includes a driving transistor, a bias transistor, and a gate initialization transistor, the signal line includes a bias signal line and a first reference signal line, the bias transistor is electrically connected between at least one of a first electrode and a second electrode of the driving transistor and the bias signal line, and the gate initialization transistor is electrically connected between a gate of the driving transistor and the first reference signal line. The bias signal line includes a first sub-bias signal line extending along a first direction and arranged along a second direction, and a second sub-bias signal line extending along the second direction and arranged along the first direction, the first direction intersects with the second direction, and the first sub-bias signal line is electrically connected to the second sub-bias signal line. The first reference signal line includes a first sub-reference signal line extending along the first direction and arranged along the second direction, and a second sub-reference signal line extending along the second direction and arranged along the first direction, and the first sub-reference signal line is electrically connected to the second sub-reference signal line. The bias signal line and the first reference signal line are insulated from each other.

In one embodiment, a display device is provided according to an embodiment of the present disclosure. The display device includes the display panel described above.

### BRIEF DESCRIPTION OF THE DRAWINGS

In order to illustrate the embodiments of the present disclosure or in the conventional technology more clearly, drawings to be used in the embodiments or the conventional technology are described simply hereinafter. Apparently, the drawings in the following description are only some examples of the present disclosure.

FIG. 1 is a schematic cross-sectional structural view of a display panel according to an embodiment of the present disclosure;

FIG. 2 is a schematic partial top view of a display panel according to an embodiment of the present disclosure;

FIG. 3 is a schematic structural diagram of a pixel circuit in a display panel according to an embodiment of the present disclosure;

FIG. 4 is a schematic structural diagram of a pixel circuit in a display panel according to another embodiment of the present disclosure;

FIG. 4a is a timing diagram of signals provided to the pixel circuit shown in FIG. 4 during a driving cycle according to an embodiment of the present disclosure;

FIG. 5 is a schematic diagram of a partial layout structure of a display panel according to an embodiment of the present disclosure;

FIG. 6 is a schematic partial enlarged view of the layout structure shown in FIG. 5;

FIG. 7a is a schematic diagram of a layout structure of an active layer poly in the layout structure shown in FIG. 5;

FIG. 7b is a schematic diagram of a layout structure of a metal layer M1 in the layout structure shown in FIG. 5;

FIG. 7c is a schematic diagram of a layout structure of a metal layer MC in the layout structure shown in FIG. 5;

FIG. 7d is a schematic diagram of a layout structure of an oxide layer IGZO in the layout structure shown in FIG. 5;

FIG. 7e is a schematic diagram of a layout structure of a metal layer MG in the layout structure shown in FIG. 5;

FIG. 7f is a schematic diagram of a layout structure of a metal layer M2 in the layout structure shown in FIG. 5;

FIG. 8 is a schematic diagram of a partial layout structure of a display panel according to another embodiment of the present disclosure;

FIG. 9a is a schematic diagram of a layout structure of a metal layer M3 in the layout structure shown in FIG. 8;

FIG. 9b is a schematic diagram of a layout structure of a metal layer M4 in the layout structure shown in FIG. 8;

FIG. 9c is a schematic diagram of a layout structure of a metal layer RE in the layout structure shown in FIG. 8;

FIG. 10 is a schematic diagram of a partial layout structure of a display panel according to another embodiment of the present disclosure;

FIG. 11a is a schematic diagram of a layout structure of an active layer poly in the layout structure shown in FIG. 10;

FIG. 11b is a schematic diagram of a layout structure of a metal layer M1 in the layout structure shown in FIG. 10;

FIG. 11c is a schematic diagram of a layout structure of a metal layer MC in the layout structure shown in FIG. 10;

FIG. 11d is a schematic diagram of a layout structure of an oxide layer IGZO in the layout structure shown in FIG. 10;

FIG. 11e is a schematic diagram of a layout structure of a metal layer MG in the layout structure shown in FIG. 10;

FIG. 11f is a schematic diagram of a layout structure of a metal layer M2 in the layout structure shown in FIG. 10;

FIG. 12 is a schematic diagram of a partial layout structure of a display panel according to another embodiment of the present disclosure;

FIG. 13a is a schematic diagram of a layout structure of an active layer poly in the layout structure shown in FIG. 12;

FIG. 13b is a schematic diagram of a layout structure of a metal layer M1 in the layout structure shown in FIG. 12;

FIG. 13c is a schematic diagram of a layout structure of a metal layer MC in the layout structure shown in FIG. 12;

FIG. 13d is a schematic diagram of a layout structure of an oxide layer IGZO in the layout structure shown in FIG. 12;

FIG. 13e is a schematic diagram of a layout structure of a metal layer MG in the layout structure shown in FIG. 12;

FIG. 13f is a schematic diagram of a layout structure of a metal layer M2 in the layout structure shown in FIG. 12;

FIG. 14 is a schematic top view of a display panel according to another embodiment of the present disclosure;

FIG. 15 is a schematic diagram of a local layout structure formed by a metal layer M3, a metal layer M4, and a metal layer RE that are stacked in a display panel according to an embodiment of the present disclosure;

FIG. 16 is a schematic diagram of a local layout structure formed by a metal layer M3, a metal layer M4, and a metal layer RE that are stacked in a display panel according to another embodiment of the present disclosure; and

FIG. 17 is a schematic top view of a display device according to an embodiment of the present disclosure.

### DETAILED DESCRIPTION

The embodiments of the present disclosure are clearly and completely described below in conjunction with the drawings of the embodiments of the present disclosure. Apparently, the embodiments described are only some embodiments of the present disclosure, rather than all of the embodiments.

Various details are set forth in the following description to facilitate a full understanding of the present disclosure. However, the present disclosure may be implemented in other ways different from those described herein.

The present disclosure is described in detail in conjunction with schematic diagrams. For ease of illustration, when the embodiments of the present disclosure are described in detail, a cross-sectional view showing a device structure is partially enlarged without being shown according to a general scale. The schematic diagrams are only examples, which are not intended to limit the protection scope of the present disclosure. In addition, three-dimensional spatial sizes of a length, a width and a depth should be included in an actual production.

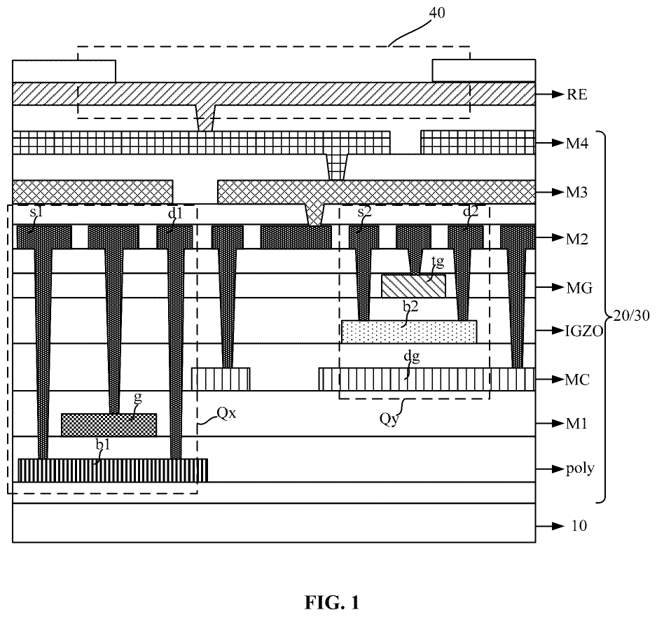

FIG. 1 is a schematic cross-sectional structural view of a display panel according to an embodiment of the present disclosure. As shown in FIG. 1, the display panel includes a substrate 10, a pixel circuit 20 and a signal line 30 that are arranged on a side of the substrate 10, and a light-emitting element 40.

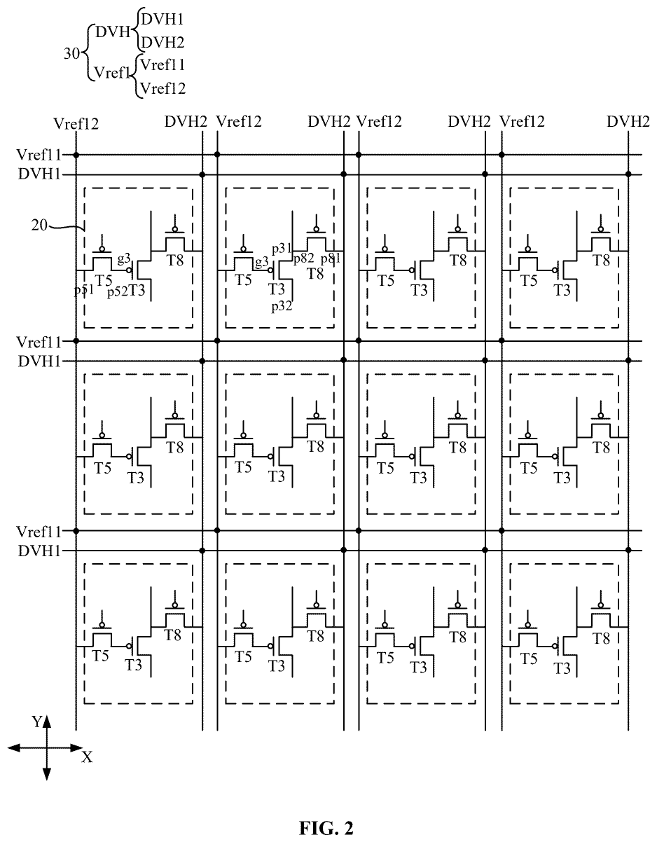

FIG. 2 is a schematic partial top view of a display panel according to an embodiment of the present disclosure. As shown in FIG. 2, in the display panel, the pixel circuit 20 includes a driving transistor T3, a bias transistor T8, and a gate initialization transistor T5. The signal line 30 includes a bias signal line DVH and a first reference signal line Vref1. The bias transistor T8 is electrically connected between at least one of a first electrode p31 and a second electrode p32 of the driving transistor T3 and the bias signal line DVH. The gate initialization transistor T5 is electrically connected between a gate g3 of the driving transistor T3 and the first reference signal line Vref1.

It can be understood that the signal line 30 is configured to provide at least one of a voltage signal and a current signal for the pixel circuit 20. The pixel circuit 20 is configured to drive the light-emitting element 40 to emit light and control a brightness of the light-emitting element. In an embodiment, the display panel includes pixel circuits 20 arranged in an array and light-emitting elements 40 arranged in an array. Each of the pixel circuits 20 drives a corresponding light-emitting element 40 to emit light based on a target brightness, and the display panel displays a target screen.

In one embodiment, as shown in FIG. 2, a first electrode p81 of the bias transistor T8 is electrically connected to the bias signal line DVH, and a second electrode p82 of the bias transistor T8 is electrically connected to at least one of the first electrode p31 and the second electrode p32 of the driving transistor T3. In other words, the second electrode p82 of the bias transistor T8 may be only electrically connected to the first electrode p31 of the driving transistor T3. In one embodiment, the second electrode p82 of the bias transistor T8 may be only electrically connected to the second electrode p32 of the driving transistor T3. In one embodiment, the second electrode p82 of the bias transistor T8 may be electrically connected to both the first electrode p31 of the driving transistor T3 and the second electrode p32 of the driving transistor T3. FIG. 2 only illustrates an example that the second electrode p82 of the bias transistor T8 is electrically connected to the first electrode p31 of the driving transistor T3.

When the bias transistor T8 is turned on, the bias transistor T8 may transmit an adjustment signal transmitted on the bias signal line DVH to at least one of the first electrode p31 and the second electrode p32 of the driving transistor T3, to bias at least one of the first electrode p31 and the second electrode p32 of the driving transistor T3, improve a brightness of a first frame during screen display, avoiding a low brightness of the first frame, and ensure consistency of the screen display. In addition, before the gate g3 of the driving transistor T3 is reset, the bias transistor T8 is controlled to be turned on, a bias voltage provided by the bias signal line DVH may be written into at least one of the first electrode p31 and the second electrode p32 of the driving transistor T3, to refresh at least one of a potential of the first electrode p31 and a potential of the second electrode p32 of the driving transistor T3, and a device characteristic of the driving transistor T3 is set to a predetermined initial state, eliminating the impact of a data signal written into a previous frame on the device characteristic of the driving transistor T3. After a data voltage is written into the driving transistor T3, electric leakage occurs in at least one of the first electrode p31 and the second electrode p32 of the driving transistor T3. Especially under low-frequency driving, the electric leakage is more serious, resulting in a significant deviation in at least one of the potential of the first electrode p31 and the potential of the second electrode p32 of the driving transistor T3. In such case, the bias transistor T8 is controlled to be turned on, the bias voltage is written into at least one of the first electrode p31 and the second electrode p32 of the driving transistor T3 by using the bias transistor T8, and a bias state of the driving transistor T3 may be maintained to be the same as a bias state when the data voltage is just written, improving the stability of an operating state of the driving transistor T3, and avoiding a low-frequency flicker, to improve the display effect of the display panel.

As shown in FIG. 2, a first electrode p51 of the gate initialization transistor T5 is electrically connected to the first reference signal line Vref1, and a second electrode p52 of the gate initialization transistor T5 is electrically connected to the gate g3 of the driving transistor T3. When the gate initialization transistor T5 is turned on, the gate initialization transistor T5 may transmit a reference signal transmitted on the first reference signal line Vref1 to the gate g3 of the driving transistor T3, to initialize (also known as reset) the gate g3 of the driving transistor T3.

As shown in FIG. 2, the bias signal line DVH includes a first sub-bias signal line DVH1 extending along a first direction X and arranged along a second direction Y, and a second sub-bias signal line DVH2 extending along the second direction Y and arranged along the first direction X. The first direction X intersects with the second direction Y. The first sub-bias signal line DVH1 is electrically connected to the second sub-bias signal line DVH2.

In an embodiment, the number of the first sub-bias signal line DVH1 and the number of the second sub-bias signal line DVH2 each may be more than one. Multiple first sub-bias signal lines DVH1 intersect with multiple second sub-bias signal lines DVH2 at multiple positions. The first sub-bias signal line DVH1 is electrically connected to the second sub-bias signal line DVH2 at all intersection positions between the first sub-bias signal lines DVH1 and the second sub-bias signal lines DVH2, as shown in FIG. 2. In one embodiment, the first sub-bias signal line DVH1 is electrically connected to the second sub-bias signal line DVH2 at some of the intersection positions between the first sub-bias signal lines DVH1 and the second sub-bias signal lines DVH2. In one embodiment, each of the first sub-bias signal lines DVH1 may be electrically connected to at least one of the second sub-bias signal lines DVH2, and each of the second sub-bias signal lines DVH2 may be electrically connected to at least one of the first sub-bias signal lines DVH1.

As shown in FIG. 2, the first reference signal line Vref1 includes a first sub-reference signal line Vref11 extending along the first direction X and arranged along the second direction Y, and a second sub-reference signal line Vref12 extending along the second direction Y and arranged along the first direction X. The first sub-reference signal line Vref11 is electrically connected to the second sub-reference signal line Vref12.

In an embodiment, the number of the first sub-reference signal line Vref11 and the number of the second sub-reference signal line Vref12 each may be more than one. Multiple first sub-reference signal lines Vref11 intersect with multiple second sub-reference signal lines Vref12 at multiple positions. The first sub-reference signal lines Vref11 is electrically connected to the second sub-reference signal line Vref12 at all intersection positions between the first sub-reference signal lines Vref11 and the second sub-reference signal lines Vref12, as shown in FIG. 2. In one embodiment, the first sub-reference signal line Vref11 is electrically connected to the second sub-reference signal line Vref12 at some of the intersection positions between the first sub-reference signal lines Vref11 and the second sub-reference signal lines Vref12. In one embodiment, each of the first sub-reference signal lines Vref11 may be electrically connected to at least one of the second sub-reference signal lines Vref12, and each of the second sub-reference signal lines Vref12 may be electrically connected to at least one of the first sub-reference signal lines Vref11.

In some embodiments, as shown in FIG. 2, the first direction X is perpendicular to the second direction Y. In one embodiment, the first direction X is a row direction, and the second direction Y is a column direction. In other embodiments, the first direction X may not be perpendicular to the second direction Y, and the first direction X and the second direction Y may have an angle greater than 0 degrees and less than 90 degrees.

It can be understood that the bias signal line DVH is insulated from the first reference signal line Vref1, that is, the first sub-bias signal line DVH1 in the bias signal line DVH is insulated from the first sub-reference signal line Vref11 and the second sub-reference signal line Vref12 in the first reference signal line Vref1. The second sub-bias signal line DVH2 in the bias signal line DVH is also insulated from the first sub-reference signal line Vref11 and the second sub-reference signal line Vref12 in the first reference signal line Vref1. Similarly, the first sub-reference signal line Vref11 in the first reference signal line Vref1 is insulated from the first sub-bias signal line DVH1 and the second sub-bias signal line DVH2 in the bias signal line DVH, and the second sub-reference signal line Vref12 in the first reference signal line Vref1 is also insulated from the first sub-bias signal line DVH1 and the second sub-bias signal line DVH2 in the bias signal line DVH.

It can be seen that in the display panel according to the embodiment of the present disclosure, the bias signal line DVH includes the first sub-bias signal line DVH1 and the second sub-bias signal line DVH2 that extend along different directions, which are electrically connected to each other and intersect with each other, to form the bias signal line DVH with a grid structure, which reduces overall resistance of the bias signal line DVH, to reduce the power consumption of the bias signal line DVH, and improve the signal transmission stability of the bias signal line DVH, which is beneficial for improving the display uniformity and other display effects of the display panel. Similarly, the first reference signal line Vref1 includes the first sub-reference signal line Vref11 and the second sub-reference signal line Vref12 that extend along different directions, which are electrically connected to each other and intersect with each other, to form the first reference signal line Vref1 with a grid structure, which reduces overall resistance of the first reference signal line Vref1, to reduce the power consumption of the first reference signal line Vref1 and improve the signal transmission stability of the first reference signal line Vref1, which is beneficial for enhancing the display uniformity and other display effects of the display panel.

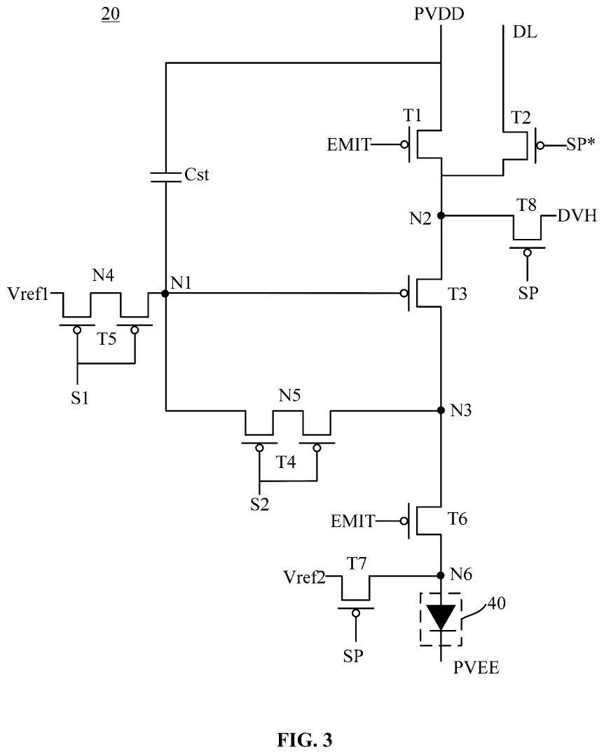

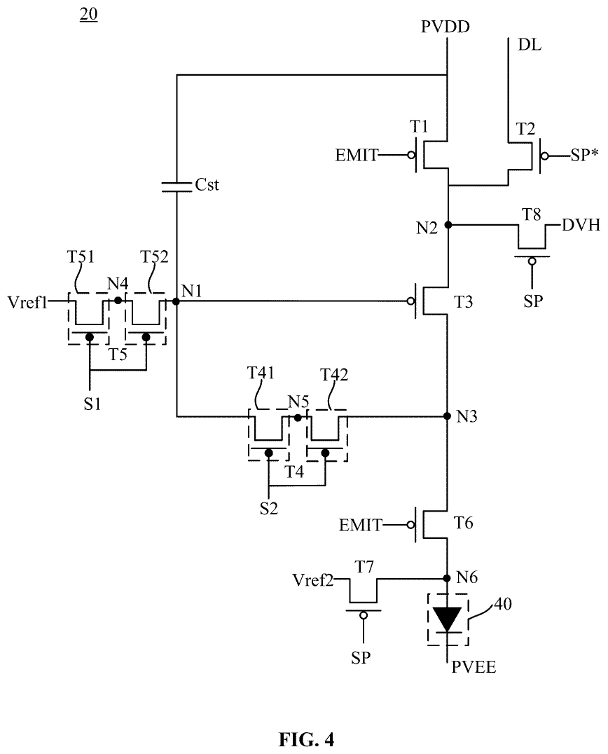

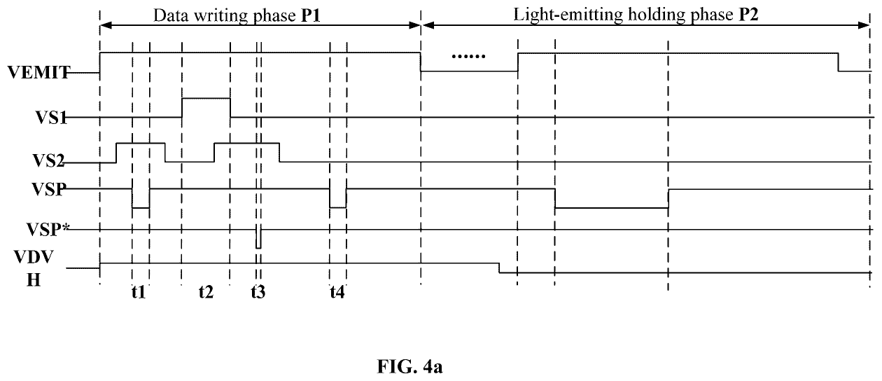

In an embodiment, FIGS. 3 and 4 respectively illustrate schematic structural diagrams of two types of pixel circuits 20 in a display panel according to an embodiment of the present disclosure. As shown in FIGS. 3 and 4, the pixel circuit 20 includes a first light-emitting control transistor T1, a data writing transistor T2, a driving transistor T3, a compensation transistor T4, a gate initialization transistor T5, a second light-emitting control transistor T6, an anode initialization transistor T7, a bias transistor T8, and a storage capacitor Cst. The signal line 30 includes a scanning signal line, a reference signal line, a power supply signal line, and a data signal line DL. The scanning signal line includes a first scanning signal line S1, a second scanning signal line S2, a third scanning signal line SP*, a bias control signal line SP, and a light-emitting control signal line EMIT. The reference signal line includes at least one of the first reference signal line Vref1 and a second reference signal line Vref2. The power supply signal line includes a first power signal line PVDD and a second power signal line PVEE.

A first electrode of the first light-emitting control transistor T1 is electrically connected to the first power signal line PVDD, a second electrode of the first light-emitting control transistor T1 is electrically connected to a second node N2, and a gate of the first light-emitting control transistor T1 is electrically connected to the light-emitting control signal line EMIT.

A first electrode of the data writing transistor T2 is electrically connected to the data signal line DL, a second electrode of the data writing transistor T2 is electrically connected to the second node N2, and a gate of the data writing transistor T2 is electrically connected to the third scanning signal line SP*.

A first electrode of the driving transistor T3 is electrically connected to the second node N2, a second electrode of the driving transistor T3 is electrically connected to a third node N3, and a gate of the driving transistor T3 is electrically connected to a first node N1.

A first electrode of the compensation transistor T4 is electrically connected to the third node N3, a second electrode of the compensation transistor T4 is electrically connected to the first node N1, and a gate of the compensation transistor T4 is electrically connected to the second scanning signal line S2.

A first electrode of the gate initialization transistor T5 is electrically connected to the first reference signal line Vref1, a second electrode of the gate initialization transistor T5 is electrically connected to the first node N1, and a gate of the gate initialization transistor T5 is electrically connected to the first scanning signal line S1.

A first electrode of the second light-emitting control transistor T6 is electrically connected to the third node N3, a second electrode of the second light-emitting control transistor T6 is electrically connected to a sixth node N6, and a gate of the second light-emitting control transistor T6 is electrically connected to the light-emitting control signal line EMIT.

A first electrode of the anode initialization transistor T7 is electrically connected to the second reference signal line Vref2, a second electrode of the anode initialization transistor T7 is electrically connected to the sixth node N6, and a gate of the anode initialization transistor T7 is electrically connected to the bias control signal line SP.

A first electrode of the bias transistor T8 is electrically connected to the bias signal line DVH, a second electrode of the bias transistor T8 is electrically connected to the second node N2, and a gate of the bias transistor T8 is electrically connected to the bias control signal line SP.

A first electrode plate of the storage capacitor Cst is electrically connected to the first node N1, and a second electrode plate of the storage capacitor Cst is electrically connected to the first power signal line PVDD.

Thus, the pixel circuit 20 with an 8T1C structure is implemented.

It can be understood that the first node N1, the second node N2, the third node N3, and a fourth node N4 may be virtual connection nodes or real connection nodes.

It should be noted that the pixel circuits 20 shown in FIGS. 3 and 4 are merely exemplary. In practice, the pixel circuit 20 with other structures may be selected based on requirements, which is not limited to the pixel circuits 20 with the 8T1C structure shown in FIGS. 3 and 4.

It should be noted that the first reference signal line Vref1 and the second reference signal line Vref2 may transmit a same reference signal, that is, the node N1 and the node N6 are reset by using one reference signal. In other embodiments, the first reference signal line Vref1 and the second reference signal line Vref2 may transmit different reference signals, that is, a reset voltage of the node N1 may not be equal to a reset voltage of the node N6, which is not limited in the present disclosure, depending on the situation.

As shown in FIGS. 1, 3, and 4, each of the film transistors in the pixel circuit 20 may be a low temperature polycrystalline (LTPS) thin film transistor Qx. The LTPS thin film transistor Qx includes an active layer b1, a gate g, a source s1, and a drain d1. In one embodiment, the film transistor may be an indium gallium zinc oxide (IGZO) thin film transistor Qy. The IGZO thin film transistor Qy includes an oxide layer b2, a bottom gate dg, a top gate tg, a source s2, and a drain d2.

As shown in FIGS. 3 and 4, each of the compensation transistor T4 and the gate initialization transistor T5 may be a dual-gate transistor to reduce a leakage current of the transistor and improve the display effect of the display panel.

In an embodiment, as shown in FIGS. 1 and 3, each of the compensation transistor T4 and the gate initialization transistor T5 in the pixel circuit 20 may be the IGZO thin film transistor with a dual-gate structure formed by the bottom gate dg and the top gate tg. Other thin film transistors may be LTPS thin film transistors. The pixel circuit 20 may achieve low-frequency driving due to the low electric leakage of the IGZO thin film transistor. That is, the pixel circuit 20 is a low-frequency pixel circuit. In such case, each of the thin film transistors in the pixel circuit 20 may be a PMOS thin film transistor, which is not limited in the present disclosure, depending on the situation.

In one embodiment, as shown in FIGS. 1 and 4, each of the thin film transistors in the pixel circuit 20 may also be the LTPS thin film transistor. The compensation transistor T4 may include two sub-transistors T41 and T42 connected in series, and thus has the dual-gate structure. The sub-transistor T41 is connected to the sub-transistor T42 at the node N5 of the compensation transistor T4. Similarly, the gate initialization transistor T5 may also include two sub-transistors T51 and T52 connected in series, and thus has the dual-gate structure. The sub-transistor T51 is connected to the sub-transistor T52 at the node N4 of the compensation transistor T4. In such case, each of the compensation transistor T4 and the gate initialization transistor T5 may be an NMOS thin film transistor, and other thin film transistors may be the PMOS thin film transistors, which is not limited in the present disclosure, depending on the situation.

FIG. 4a is a timing diagram of signals provided to the pixel circuit shown in FIG. 4 during a driving cycle according to another embodiment of the present disclosure. As shown in FIGS. 4 and 4a, in one example, the compensation transistor T4 and the gate initialization transistor T5 are the NMOS thin film transistors, and other transistors are the PMOS thin film transistors. An enabling level may turn on a transistor, while a non-enabling level may turn off (or cutoff) the transistor. For each of a scanning signal VS1 provided by the first scanning signal line S1 and a scanning signal VS2 provided by the second scanning signal line S2, the enabling level is a high level and the non-enabling level is a low level. For each of a scanning signal VSP* provided by the third scanning signal line SP*, a bias control signal VSP provided by the bias control signal line SP, and a light-emitting control signal VEMIT provided by the light-emitting control signal line EMIT, the enabling level is a low level, and the non-enabling level is a high level.

In one embodiment, a driving cycle of the pixel circuit 20 in a low-frequency state is divided into a data writing phase P1 and a light-emitting holding phase P2. The data writing phase P1 is divided into four time periods t1 to t4. During a time period t1, the scanning signal VS2 is at the enabling level, the compensation transistor T4 is turned on; the bias control signal VSP is at the enabling level, the anode initialization transistor T7 and the bias transistor T8 are turned on, and the bias voltage provided by the bias signal line DVH may be written into at least one of the first electrode and the second electrode of the driving transistor T3, to refresh at least one of the potential of the first electrode and the potential of the second electrode of the driving transistor T3, and a device characteristic of the driving transistor T3 is set to the predetermined initial state, eliminating the impact of the data signal written into a previous frame on the device characteristic of the driving transistor T3, and resetting an anode of the light-emitting element 40. During a time period t2, the scanning signal VS1 is at the enabling level, and the gate initialization transistor T5 is turned on, and a reference signal provided by the first reference signal line Vref1 may be transmitted to the gate of the driving transistor T3 to reset the gate of the driving transistor T3. Subsequently, the scanning signal VS2 is at the enabling level, and the compensation transistor T4 is turned on, and the driving transistor T3 is connected to a diode through the turn-on compensation transistor T4. During a time period t3, the scanning signal VS2 is at the enabling level, the compensation transistor T4 is turned on; and the scanning signal VSP* is at the enabling level, the data writing transistor T2 is turned on, and a data signal transmitted by the data signal line DL is written into the gate of the driving transistor T2 (also known as the threshold capture of the driving transistor T3). During a time period t4, the bias control signal VSP is at the enabling level, the anode initialization transistor T7 is turned on and the bias transistor T8 is turned on, the bias voltage is written into at least one of the first electrode and the second electrode of the driving transistor T3 by using the bias transistor T8, and the bias state of the driving transistor T3 may be maintained to be the same as the bias state when the data voltage is just written, improving the stability of the operating state of the driving transistor T3, and avoiding the low-frequency flicker, and resetting the anode of the light-emitting element 40. During the light-emitting holding phase P2, when a light-emitting control signal VEMIT is at the enabling level, the first light-emitting control transistor T1 is turned on, and the second light-emitting control transistor T6 is turned on, and the driving transistor T3 drives the light-emitting element 40 to emit light.

It can be seen that during the data writing phase P1, the light-emitting control signal VEMIT has a non-enabling level phase, and during the light-emitting holding phase P2, the light-emitting control signal VEMIT has multiple enabling level phases and multiple non-enabling level phases. During the data writing phase P1, the scanning signal VS2 has at least one enabling level phase to transmit the data signal to the gate of the driving transistor T3, and during the light-emitting holding phase P2, the scanning signal VS2 is at the low level to control the compensation transistor T4 to be turned off. It can be understood that during the light-emitting holding phase P2, two enabling level phases of the bias control signal VSP corresponding to a non-enabling level phase of the light-emitting control signal VEMIT in FIG. 4 may be adjusted to one enabling level phase, and a duration of the enabling level phase may be increased or decreased relative to a duration of one enabling level phase of the bias control signal VSP during the data writing phase P1. A frequency of the light-emitting control signal VEMIT is greater than a frequency of the scanning signal VS2.

In practice, a duration of the light-emitting holding phase P2 may be appropriately adjusted in order to ensure that the display panel has different refresh frequencies. When the display panel is in a high-frequency driving mode, compared with a low-frequency driving mode, the display panel may only have the data writing phase P1 without the light-emitting holding phase P2, or the duration of the light-emitting holding phase P2 is minimized as much as possible. In one example, the non-enabling level of the light-emitting control signal VEMIT adjacent to the data writing phase P1 is retained, remaining time periods in the light-emitting holding phase P2 may be removed to re-enter a next data writing phase P1.

It should be noted that FIG. 1 is a schematic structural diagram of a stacked film of a display panel by an example that the pixel circuit 20 includes the LTPS thin film transistors and the IGZO thin film transistors. It can be seen that the display panel includes the substrate 10, an active layer poly arranged on a side of the substrate 10, multiple metal layers and an oxide layer IGZO that are arranged on a side of the active layer poly away from the substrate 10. The multiple metal layers includes a metal layer M1, a metal layer MC, a metal layer MG, a metal layer M2, a metal layer M3, a metal layer M4, and a metal layer RE that are arranged in a direction away from the substrate 10. The oxide layer IGZO is arranged between the metal layer MC and the metal layer MG. Different metal layers are isolated by an insulation layer, the metal layer and the active layer are isolated by an insulation layer, and the metal layer and the oxide layer are isolated by an insulation layer.

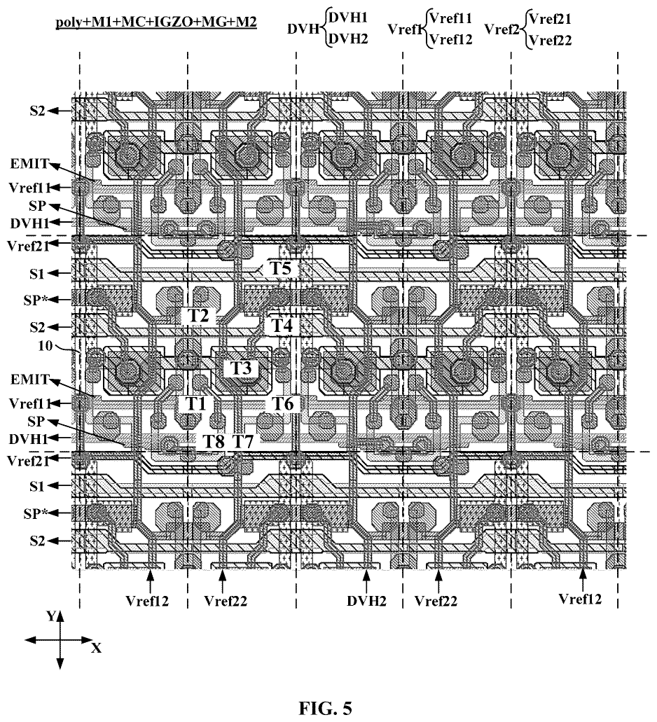

On basis of this, FIG. 5 is a schematic diagram of a partial layout structure of a display panel according to an embodiment of the present disclosure. The partial layout structure illustrates the active layer poly, the metal layer M1, the metal layer MC, the metal layer MG, and the metal layer M2. In order to clearly determine a region where each of pixel circuits is located, in FIG. 5, boundaries of regions where adjacent pixel circuits are located are represented by horizontal dashed lines and vertical dashed lines along the first direction X and the second direction Y. It can be understood that the boundaries are only for the convenience of explanation and description are not intended to limit the pixel circuit 20. Similar situations in other drawings of the present disclosure are not repeated.

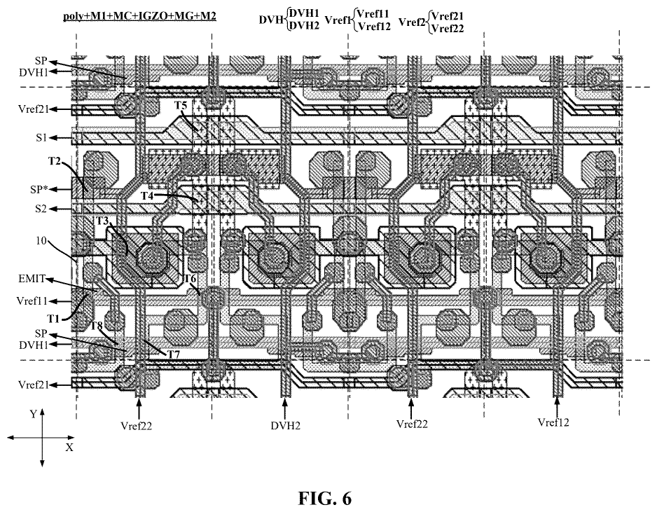

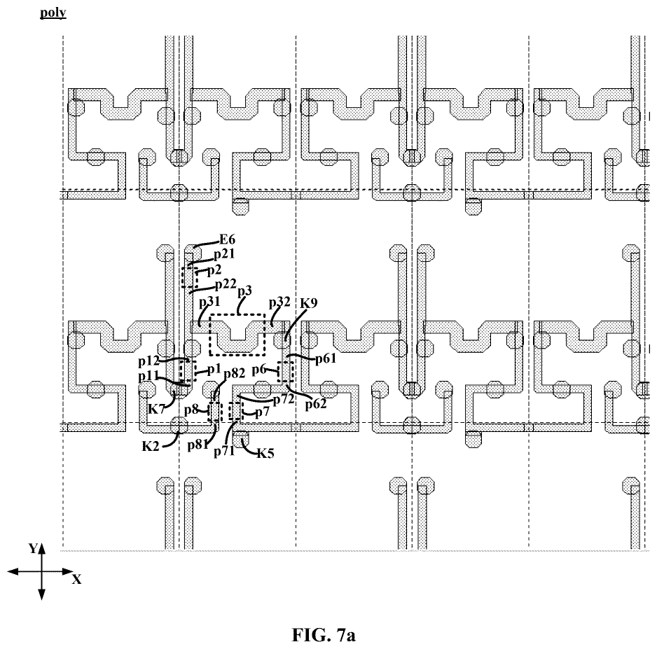

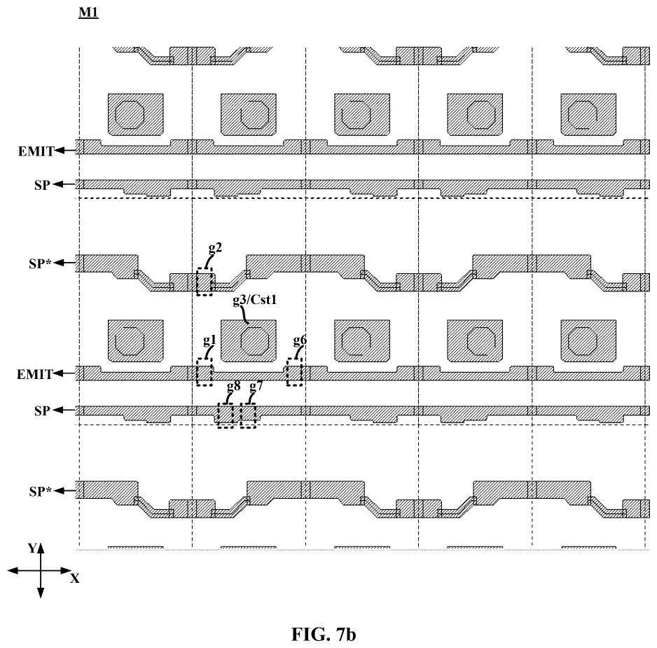

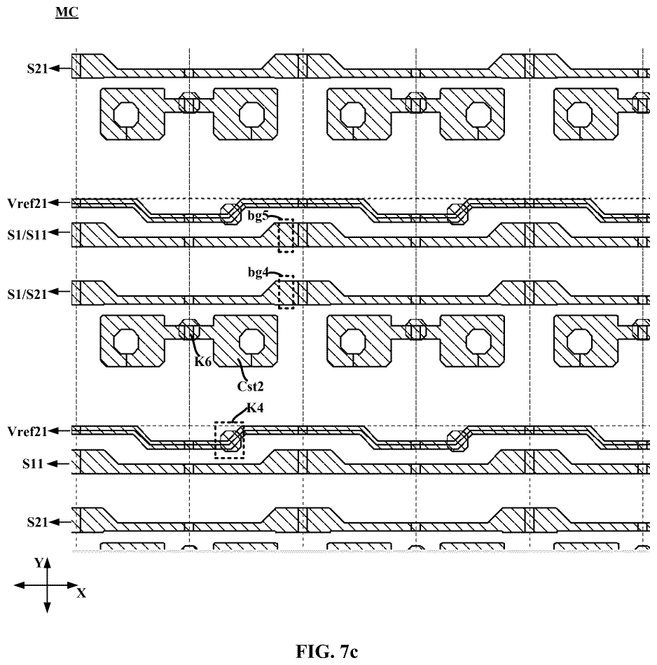

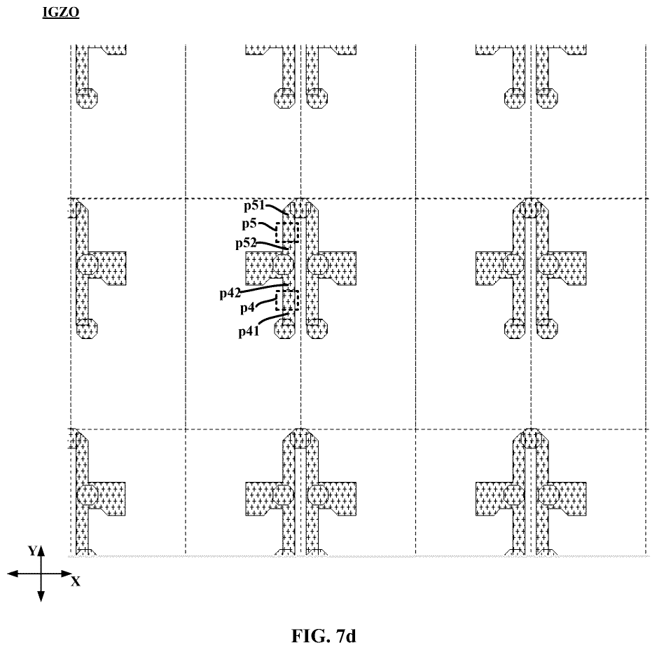

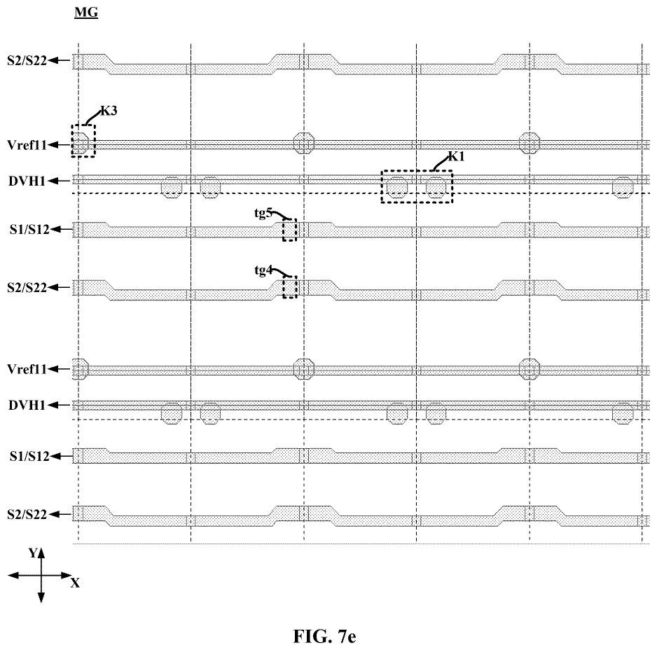

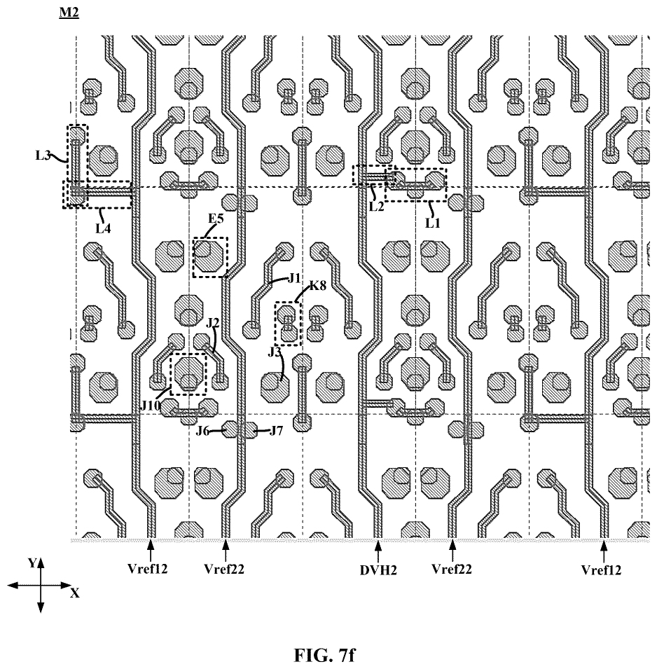

For clarity, FIG. 6 is a schematic partial enlarged view of the layout structure shown in FIG. 5, FIG. 7a is a schematic diagram of a layout structure of an active layer poly in the layout structure shown in FIG. 5, FIG. 7b is a schematic diagram of a layout structure of a metal layer M1 in the layout structure shown in FIG. 5, FIG. 7c is a schematic diagram of a layout structure of a metal layer MC in the layout structure shown in FIG. 5, FIG. 7d is a schematic diagram of a layout structure of an oxide layer IGZO in the layout structure shown in FIG. 5, FIG. 7e is a schematic diagram of a layout structure of a metal layer MG in the layout structure shown in FIG. 5, and FIG. 7f is a schematic diagram of a layout structure of a metal layer M2 in the layout structure shown in FIG. 5.

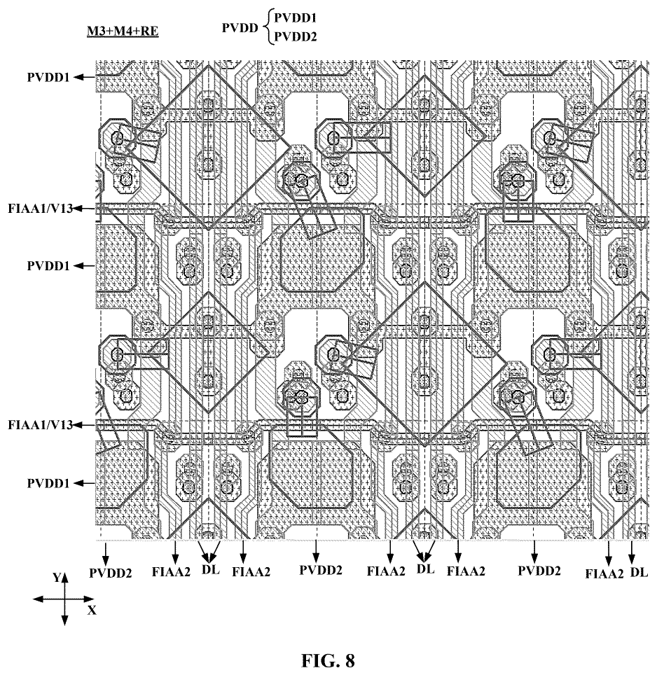

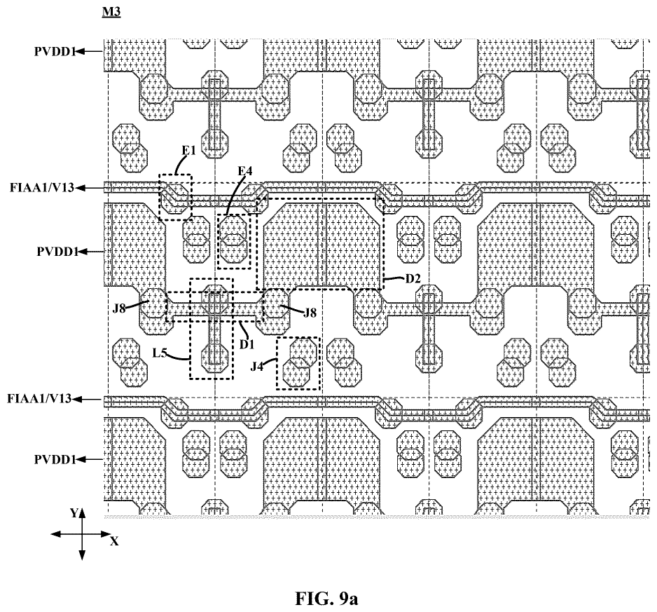

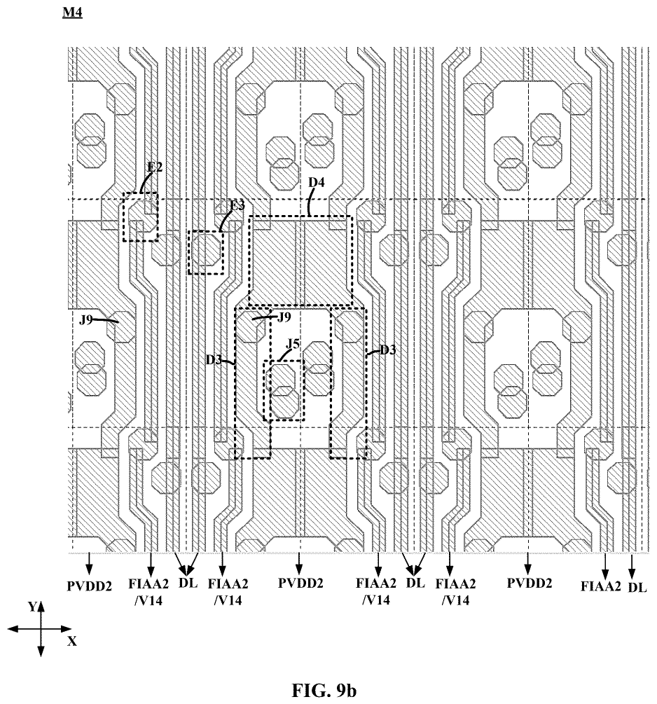

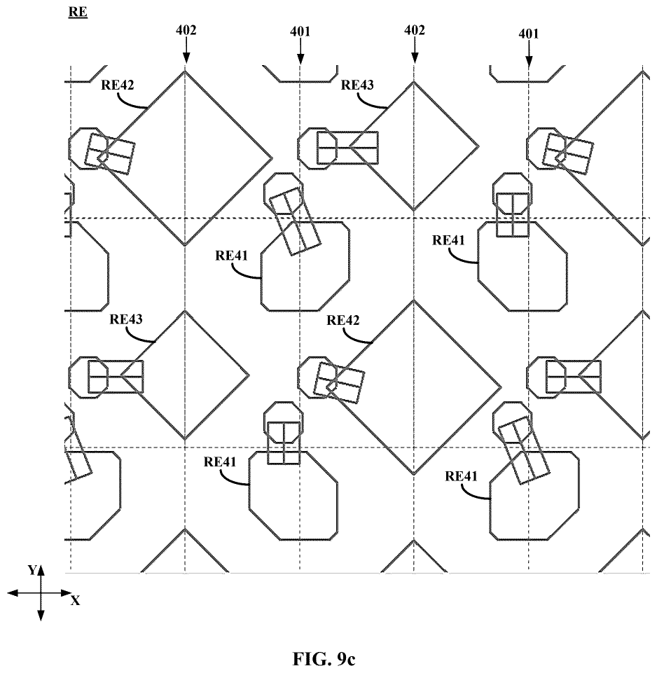

FIG. 8 is a schematic diagram of a partial layout structure of a display panel according to another embodiment of the present disclosure. The partial layout structure includes layout structures of the metal layer M3, the metal layer M4, and the metal layer RE. For clarity, FIG. 9a is a schematic diagram of a layout structure of a metal layer M3 in the layout structure shown in FIG. 8, FIG. 9b is a schematic diagram of a layout structure of a metal layer M4 in the layout structure shown in FIG. 8, and FIG. 9c is a schematic diagram of a layout structure of a metal layer RE in the layout structure shown in FIG. 8.

As shown in FIGS. 5 and 6, the pixel circuit 20 includes the driving transistor T3, the bias transistor T8, and the gate initialization transistor T5. The signal line 30 includes the bias signal line DVH and the first reference signal line Vref1. The bias signal line DVH includes the first sub-bias signal line DVH1 and the second sub-bias signal line DVH2. The first sub-bias signal line DVH1 extends along the first direction X and is arranged along the second direction Y. The second sub-bias signal line DVH2 extends along the second direction Y and is arranged along the first direction X. The first reference signal line Vref1 includes the first sub-reference signal line Vref11 and the second sub-reference signal line Vref12. The first sub-reference signal lines Vref11 extends along the first direction X and is arranged along the second direction Y. The second sub-reference signal line Vref12 extends along the second direction Y and is arranged along the first direction X.

In an embodiment, the first sub-bias signal line DVH1 and the second sub-bias signal line DVH2 are arranged in different layers, that is, signal lines extending along different directions are arranged in different metal layers to reduce difficulty of laying the signal lines in a same metal layer. In one example, as shown in FIGS. 5, 6, 7e and 7f, the first sub-bias signal line DVH1 may be arranged in the metal layer MG, and the second sub-bias signal line DVH2 may be arranged in the metal layer M2. The first sub-bias signal line DVH1 may be electrically connected to the second sub-bias signal line DVH2 through a via-hole between the metal layer MG and the metal layer M2.

In an embodiment, the first sub-reference signal line Vref11 and the second sub-reference signal line Vref12 are arranged in different layers, that is, signal lines extending along different directions are arranged in different metal layers to reduce the difficulty of laying the signal lines in a same metal layer. In one example, as shown in FIGS. 5, 6, 7e and 7f, the first sub-reference signal line Vref11 may be arranged in the metal layer MG, and the second sub-reference signal line Vref12 may be arranged in the metal layer M2. The first sub-reference signal line Vref11 may be electrically connected to the second sub-reference signal line Vref12 through a via-hole between the metal layer MG and the metal layer M2.

In an embodiment, the first sub-bias signal line DVH1 and the first sub-reference signal line Vref11 may be arranged in a same layer, that is, signal lines extending along a same direction (that is the first direction X) may be arranged in the same metal layer, reducing the occupation of the film, which is conductive to achieving a light and thin display panel.

In one embodiment, as shown in FIG. 1, the display panel includes the substrate 10 and a first metal layer MG, an oxide layer IGZO, and a second metal layer M2 that are arranged in a direction away from the substrate 10. As shown FIGS. 5, 6, and 7c to 7e, the gate initialization transistor T5 may be an oxide thin film transistor, also known as the IGZO thin film transistor. The gate initialization transistor T5 includes a first channel region p5, a first bottom gate bg5 arranged on a side of the first channel region p5 close to the substrate 10, and a first top gate tg5 arranged on a side of the first channel region p5 away from the substrate 10. The first channel region p5 is arranged in the oxide layer IGZO. The first bottom gate bg5 is arranged in the first metal layer MC. The first top gate tg5 is arranged in the second metal layer MG.

As shown in FIGS. 5, 6, and 7c to 7e, the signal line 30 further includes the first scanning signal line S1 extending along the first direction X. The first scanning signal line S1 includes a first sub-scanning signal line S11 and a second sub-scanning signal line S12 that transmit a same scanning signal. The first sub-scanning signal line S11 is arranged in the first metal layer MC and extends along the first direction X. The second sub-scanning signal line S12 is arranged in the second metal layer MG and extends along the first direction X. In a direction perpendicular to a plane where the substrate 10 is located, the first sub-scanning signal line S11, the second sub-scanning signal line S12, and the first channel region p5 of the gate initialization transistor T5 overlap with each other. In an embodiment, in the direction perpendicular to the plane where the substrate 10 is located, an overlapping part of the oxide layer IGZO with the first sub-scanning signal line S11 and the second sub-scanning signal line S12 is the first channel region p5 of the gate initialization transistor T5, and a part of the first sub-scanning signal line S11 facing the first channel region p5 of the gate initialization transistor T5 is the first bottom gate bg5 of the gate initialization transistor T5, and the first bottom gate bg5 of the gate initialization transistor T5 is electrically connected to the first sub-scanning signal line S11. A part of the second sub-scanning signal line S12 facing the first channel region p5 of the gate initialization transistor T5 is the first top gate tg5 of the gate initialization transistor T5, and the first top gate tg5 of the gate initialization transistor T5 is electrically connected to the second sub-scanning signal line S12. Therefore, both the first top gate tg5 and the first bottom gate bg5 of the gate initialization transistor T5 are electrically connected to the first scanning signal line S1 for receiving a same scanning signal.

As shown in FIGS. 5, 6, and 7d, the gate initialization transistor T5 further includes the first electrode p51 and the second electrode p52 that are connected to the first channel region p5. As shown in FIGS. 5, 6, 7d to 7f, the first electrode p51 of the gate initialization transistor T5 is electrically connected to the first sub-reference signal line Vref11 arranged in the metal layer MG through a connection portion L3 arranged in the metal layer M2 and a connection portion K3 arranged in the metal layer MG. The first electrode p51 of the gate initialization transistor T5 may also be electrically connected to the second sub-reference signal line Vref12 arranged in the metal layer M2 through a connection portion L4 arranged in the metal layer M2.

As shown in FIGS. 5, 6, and 7a, the driving transistor T3 includes a channel region p3 arranged in the active layer poly, and the first electrode p31 and the second electrode p32 that are connected to the channel region p3. As shown in FIGS. 5, 6, 7a, and 7b, the driving transistor T3 further includes the gate g3 arranged in the metal layer M1. In the direction perpendicular to the plane where the substrate 10 is located, the gate g3 of the driving transistor T3 at least partially overlaps with the channel region p3 of the driving transistor T3. As shown in FIGS. 5, 6, 76, 7d, and 7f, the gate g3 of the driving transistor T3 is electrically connected to the second electrode p52 of the gate initialization transistor T5 through a connection portion J1 arranged in the metal layer M2.

As shown in FIGS. 5, 6, and 7b, the signal line 30 further includes the bias control signal line SP. The bias control signal line SP is arranged in the metal layer M1 and extends along the first direction X.

As shown in FIGS. 5, 6, and 7a, the bias transistor T8 includes a channel region p8 arranged in the active layer poly, and the first electrode p81 and the second electrode p82 that are connected to the channel region p8. As shown in FIGS. 5, 6, 7a, and 7b, the channel region p8 of the bias transistor T8 at least partially overlaps with the bias control signal line SP in the direction perpendicular to the plane where the substrate 10 is located. In an embodiment, in the direction perpendicular to the plane where the substrate 10 is located, an overlapping part of the active layer poly with the bias control signal line SP is the channel region p8 of the bias transistor T8, and an overlapping part of the bias control signal line SP with the channel region p8 of the bias transistor T8 is the gate g8 of the bias transistor T8, and the gate g8 of the bias transistor T8 is electrically connected to the bias control signal line SP.

As shown in FIGS. 5, 6, 7a, 7e, and 7f, the first electrode p81 of the bias transistor T8 is electrically connected to the first sub-bias signal line DVH1 arranged in the metal layer MG through a connection portion L1 arranged in the metal layer M2 and a connection portion K1 arranged in the metal layer MG, and the first electrode p81 of the bias transistor T8 may further be electrically connected to the second sub-bias signal line DVH2 arranged in the metal layer M2 through the connection portion L1 and a connection portion L2 that are arranged in the metal layer M2. The second electrode p82 of the bias transistor T8 is electrically connected to the first electrode p31 of the driving transistor T3 through a connection portion J2 arranged in the metal layer M2.

It can be seen that, as shown in FIGS. 5, 6, and 7e, both the first sub-bias signal line DVH1 and the first sub-reference signal line Vref11 may be arranged in the second metal layer MG, and are insulated from each other to avoid signal crosstalk. In addition, both the first sub-bias signal lines DVH1 and the first sub-reference signal lines Vref11 are arranged in the same layer as the first top gate tg5 of the gate initialization transistor T5. Therefore, both the first sub-bias signal line DVH1 and the first sub-reference signal line Vref11 are insulated from the first top gate tg5 of the gate initialization transistor T5.

It should be noted that for the convenience of description, in the present disclosure, a region of each of the transistors arranged in the active layer poly is divided, and a region of each of the transistors arranged in the oxide layer IGZO is divided, in one example, the first electrode p31 and the second electrode p32 of the driving transistor T3 are arranged in the active layer poly, and the first electrode p51 and the second electrode p52 of the gate initialization transistor T5 are arranged in the oxide layer IGZO. However, it can be understood that the division is not intended to limit a specific region, different names and markings are only for better explain and illustrate the embodiments of the present disclosure.

In an embodiment, as shown in FIGS. 5, 6, and 7e, pixel circuits 20 is arranged in an array along the first direction X and the second direction Y. The first direction X is the row direction. The pixel circuits 20 are arranged in rows N10. The number of the first sub-bias signal line DVH1 is N11, and the number of the first sub-reference signal line Vref11 is N12. N11≤N10, N12≤N10, each of N10, N11, and N12 represents a positive integer. That is, the pixel circuits 20 are arranged in the rows N10 as a reference, the number of the first sub-bias signal line DVH1 may be equal to or less than the rows N10 of the pixel circuits 20, and the number of the first sub-reference signal line Vref11 may also be equal to or less than the rows N10 of the pixel circuits 20.

In some embodiments, as shown in FIGS. 5, 6, and 7e, for the pixel circuits 20 arranged in each of the rows, one first sub-bias signal line DVH1 and one first sub-reference signal line Vref11 may be arranged corresponding to the pixel circuits 20 arranged in the row. In such case, N11=N12=N10. Such arrangement is conductive to increasing the number of the first sub-bias signal line DVH1 and the number of the first sub-reference signal line Vref11, and reducing resistance of the bias signal line DVH and resistance of the first reference signal line Vref1, to reduce the power consumption of the bias signal line DVH and the power consumption of the first reference signal line Vref1, and improve the signal transmission stability of the bias signal line DVH and the signal transmission stability of the first reference signal line Vref1.

In other embodiments, the first sub-bias signal line DVH1 is arranged corresponding to the pixel circuits 20 arranged in a part of the rows, and the first sub-reference signal line Vref11 is arranged corresponding to the pixel circuits 20 arranged in other rows. In such case, N11<N10, and N12<N10. In such way, a layout density of the first sub-bias signal lines DVH1 and the first sub-reference signal lines Vref11 that extend along a same direction (that is, the first direction X) is reduced, reducing a layout space of the pixel circuits 20 and increasing the pixel density of the display panel, which is conductive to achieving high-resolution and high-definition display.

In an embodiment, the first sub-bias signal lines DVH1 and the first sub-reference signal lines Vref11 are alternately arranged along the second direction Y. In such way, N11+N12≤N10, and the distribution uniformity of the first sub-bias signal line DVH1 and the distribution uniformity of the first sub-reference signal line Vref11 are improved, to improve the wiring uniformity within the film, which is conducive to improving the overall signal consistency of the display panel.

The first sub-bias signal line DVH1 and the first sub-reference signal line Vref11 may be alternately arranged based on a quantity ratio. In one example, one first sub-bias signal line DVH1 and one first sub-reference signal line Vref11 are alternately arranged with a quantity ratio of 1:1. In one embodiment, two first sub-bias signal lines DVH1 and one first sub-reference signal line Vref11 are alternately arranged with a quantity ratio of 2:1. In one embodiment, the first sub-bias signal line DVH1 and the first sub-reference signal line Vref11 are alternately arranged based on other quantity ratios, which is not limited in the present disclosure, depending on the situation.

It should be noted that in the present disclosure, one signal line 30 is arranged corresponding to one row of the pixel circuits 20, which indicates that one row of the pixel circuits 20 at least partially overlaps with one signal line 30 in the direction perpendicular to the plane where the substrate 10 is located. In one example, one first sub-bias signal line DVH1 and one first sub-reference signal line Vref11 are arranged corresponding to one row of the pixel circuits 20, which indicates that one row of the pixel circuits 20 at least partially overlaps with one first sub-bias signal line DVH1 in the direction perpendicular to the plane where the substrate 10 is located, and one row of the pixel circuits 20 at least partially overlaps with one first sub-reference signal line Vref11 in the direction perpendicular to the plane where the substrate 10 is located, which are not repeated herein.

As shown in FIG. 1, the display panel further includes the light-emitting element 40. The light-emitting element 40 includes an anode RE, a light-emitting layer (not shown), and a cathode (not shown) that are arranged in the direction away from the substrate 10. As shown in FIGS. 3 to 6, the pixel circuit 20 further includes the anode initialization transistor T7. The anode initialization transistor T7 is electrically connected to the anode RE of the light-emitting element 40. The signal line 30 further includes the bias control signal line SP. The bias control signal line SP is electrically connected to the gate of the anode initialization transistor T7 and the gate of the bias transistor T8.

As shown in FIGS. 5, 6, 7a, and 7b, the anode initialization transistor T7 includes a channel region p7 arranged in the active layer poly, and the bias transistor T8 includes the channel region p8 arranged in the active layer poly. The bias control signal line SP may be arranged in the metal layer M1 along the first direction X. In the direction perpendicular to the plane where the substrate 10 is located, the bias control signal line SP at least partially overlaps with the channel region p7 of the anode initialization transistor T7, and also at least partially overlaps with the channel region p8 of the bias transistor T8. In an embodiment, in the direction perpendicular to the plane where the substrate 10 is located, an overlapping part of the bias control signal line SP with the channel region p7 of the anode initialization transistor T7 is the gate g7 of the anode initialization transistor T7, and the bias control signal line SP is electrically connected to the gate of the anode initialization transistor T7. An overlapping part of the bias control signal line SP with the channel region p8 of the bias transistor T8 is the gate g8 of bias transistor T8, and the bias control signal line SP is electrically connected to the gate g8 of the bias transistor T8.

As shown in FIGS. 5, 6, and 7a, the anode initialization transistor T7 further includes a first electrode p71 and a second electrode p72 that are connected to the channel region p7. As shown in FIGS. 7a, 7f, 8, and 9a to 9c, the second electrode p72 of the anode initialization transistor T7 is electrically connected to the anode RE of the light-emitting element through a connection portion J3 arranged in the metal layer M2, a connection portion J4 arranged in the metal layer M3, and a connection portion J5 arranged in the metal layer M4.

As shown in FIGS. 5, 6, 7b, and 7f, the bias control signal line SP extends along the first direction X, the bias control signal line SP and the first sub-bias signal line DVH1 are arranged in different layers. In an embodiment, the bias control signal line SP is arranged in the metal layer M1, and the first sub-bias signal line DVH1 is arranged in the metal layer MG. In the direction perpendicular to the plane where the substrate 10 is located, the first sub-bias signal line DVH1 at least partially overlaps with the bias control signal line SP.

It should be noted that the bias control signal line SP is arranged in the metal layer M1, the first sub-bias signal line DVH1 is arranged in the metal layer MG, and the metal layer MC, the oxide layer IGZO, and the multiple insulation layers are at least arranged between the metal layer M1 and the metal layer MG. Therefore, in the direction perpendicular to the plane where the substrate 10 is located, even if the first sub-bias signal line DVH1 at least partially overlaps with the bias control signal line SP, coupling between the first sub-bias signal line DVH1 and the bias control signal line SP is small, and the signal transmitted by the first sub-bias signal line DVH1 and the signal transmitted by the bias control signal line SP do not interfere with each other. Moreover, such arrangement may greatly reduce the layout density of the signal lines extending along the first direction X, which is conducive to reducing the layout space of the pixel circuits 20, increasing the pixel density of the display panel, and achieving the high-resolution and high-definition display.

As shown in FIGS. 3 to 6, the pixel circuit 20 further includes the first light-emitting control transistor T1 and the second light-emitting control transistor T6. The signal line 30 further includes the first power signal line PVDD and the light-emitting control signal line EMIT. The first light-emitting control transistor T1 is electrically connected between the first power signal line PVDD and the first electrode of the driving transistor T3. The second light-emitting control transistor T6 is electrically connected between the second electrode of the driving transistor T3 and the light-emitting element 40. The light-emitting control signal line EMIT is electrically connected to the gate of the first light-emitting control transistor T1 and the gate of the second light-emitting control transistor T6.

As shown in FIGS. 5, 6, 7a, and 7b, the first light-emitting control transistor T1 includes a channel region p1 arranged in the active layer poly, and the second light-emitting control transistor T6 includes a channel region p6 arranged in the active layer poly. The light-emitting control signal line EMIT may be arranged in the metal layer M1 and extend along the first direction X. In the direction perpendicular to the plane where the substrate 10 is located, the light-emitting control signal line EMIT at least partially overlaps with the channel region p1 of the first light-emitting control transistor T1, and at least partially overlaps with the channel region p6 of the second light-emitting control transistor T6. In an embodiment, in the direction perpendicular to the plane where the substrate 10 is located, an overlapping part of the light-emitting control signal line EMIT with the channel region p1 of the first light-emitting control transistor T1 is the gate g1 of the first light-emitting control transistor T1, and the light-emitting control signal line EMIT is electrically connected to the gate g1 of the first light-emitting control transistor T1; and an overlapping part of the light-emitting control signal line EMIT with the channel region p6 of the second light-emitting control transistor T6 is the gate g6 of the second light-emitting control transistor T6, and the light-emitting control signal line EMIT is electrically connected to the gate g6 of the second light-emitting control transistor T6.

As shown in FIGS. 5, 6, and 7a, the first light-emitting control transistor T1 further includes a first electrode p11 and a second electrode p12 that are connected to the channel region p1. The second electrode p12 of the first light-emitting control transistor T1 is directly electrically connected to the first electrode p31 of the driving transistor T3 in the active layer poly.

As shown in FIGS. 5, 6, and 7a, the second light-emitting control transistor T6 further includes a first electrode p61 and a second electrode p62 that are connected to the channel region p6. The first electrode p61 of the second light-emitting control transistor T6 is directly electrically connected to the second electrode p32 of the driving transistor T3 in the active layer poly, and the second electrode p62 of the second light-emitting control transistor T6 is also directly electrically connected to the second electrode p72 of the anode initialization transistor T7 in the active layer poly. Moreover, as shown in FIGS. 7a, 7f, 8, and 9a to 9c, the second electrode p62 of the second light-emitting control transistor T6 and the second electrode p72 of the anode initialization transistor T7 each are electrically connected to the anode RE of the light-emitting element through the connection portion J3 arranged in the metal layer M2, the connection portion J4 arranged in the metal layer M3, and the connection portion J5 arranged in the metal layer M4.

As shown in FIGS. 5, 6, 7b, and 7f, the light-emitting control signal line EMIT extends along the first direction X and the light-emitting control signal line EMIT and the first sub-reference signal line Vref11 are arranged in different layers. In an embodiment, the light-emitting control signal line EMIT is arranged in the metal layer M1, and the first sub-reference signal line Vref11 is arranged in the metal layer MG. In the direction perpendicular to the plane where the substrate 10 is located, the first sub-reference signal line Vref11 at least partially overlaps with the light-emitting control signal line EMIT.

It should be noted that the light-emitting control signal line EMIT is arranged in the metal layer M1, the first sub-reference signal line Vref11 is arranged in the metal layer MG, and the metal layer MC, the oxide layer IGZO, and multiple insulation layers are at least arranged between the metal layer M1 and the metal layer MG. Therefore, in the direction perpendicular to the plane where the substrate 10 is located, even if the first sub-reference signal line Vref11 at least partially overlaps with the light-emitting control signal line EMIT, coupling between the first sub-reference signal line Vref11 and the light-emitting control signal line EMIT is small, and the signal transmitted by the first sub-reference signal line Vref11 and the signal transmitted by the light-emitting control signal line EMIT do not interfere with each other. Moreover, such arrangement may greatly reduce the layout density of the signal lines extending along the first direction X, which is conducive to reducing the layout space of the pixel circuits 20, increasing the pixel density of the display panel, and achieving the high-resolution and high-definition display.

Furthermore, in an embodiment, the second sub-bias signal line DVH2 and the second sub-reference signal line Vref12 may be arranged in a same layer, that is, signal lines extending along a same direction (that is, the first direction Y) may be arranged in the same metal layer, reducing the occupation of the film, which is conductive to achieving the light and thin display panel. In one example, as shown in FIGS. 5, 6, and 7f, both the second sub-bias signal line DVH2 and the second sub-reference signal line Vref12 may be arranged in the metal layer M2, which are insulated from each other to avoid signal crosstalk.

Similar to the first sub-bias signal line DVH1 and the first sub-reference signal line Vref11 that are arranged in the same layer and insulated from each other, the pixel circuits 20 are arranged in an array along the first direction X and the second direction Y. The second direction X is the column direction. The pixel circuits 20 are arranged in columns N20. The number of the second sub-bias signal line DVH2 is N21. The number of the second sub-reference signal line Vref12 is N22. N21≤N20, N22≤N20, and each of N20, N21, and N22 represents a positive integer. That is, the pixel circuits 20 are arranged in the columns N20 as a reference, the number of the second sub-bias signal line DVH2 may be equal to or less than the columns N20 of the pixel circuits 20, and the number of the second sub-reference signal line Vref12 may also be equal to or less than the columns N20 of the pixel circuits 20.

In some embodiments, for the pixel circuits 20 arranged in each of the columns, one second sub-bias signal line DVH2 and one second sub-reference signal line Vref12 may be arranged corresponding to the pixel circuits 20 arranged in the column. In such case, N21=N22=N20. Such arrangement is conductive to increasing the number of the second sub-bias signal line DVH2 and the number of the second sub-reference signal line Vref12, and reducing resistance of the bias signal line DVH and resistance of the first reference signal line Vref1, to reduce the power consumption of the bias signal line DVH and the power consumption of the first reference signal line Vref1, and improve the signal transmission stability of the bias signal line DVH and the signal transmission stability of the first reference signal line Vref1.

In other embodiments, the second sub-bias signal line DVH2 is arranged corresponding to the pixel circuits 20 arranged in a part of the columns, and the second sub-reference signal line Vref12 is arranged corresponding to the pixel circuits 20 arranged in the other columns. In such case, N21<N20 and N22<N20. In such way, a layout density of the second sub-bias signal lines DVH2 and the second sub-reference signal lines Vref12 that extend along a same direction (that is, the second direction Y) is reduced, reducing a layout space of the pixel circuits 20 and increasing the pixel density of the display panel, which is conductive to achieving the high-resolution and high-definition display.

In an embodiment, the second sub-bias signal lines DVH2 and the second sub-reference signal lines Vref12 are alternately arranged along the first direction X. In such way, N21+N22≤N20, and the distribution uniformity of the second sub-bias signal lines DVH2 and the distribution uniformity of the second sub-reference signal lines Vref12 are improved, to improve the wiring uniformity within the film, which is conducive to improving the overall signal consistency of the display panel.

The second sub-bias signal lines DVH2 and the second sub-reference signal lines Vref12 may be alternately arranged based on a quantity ratio. In one example, one second sub-bias signal line DVH2 and one second sub-reference signal line Vref12 are alternately arranged with a quantity ratio of 1:1. In one embodiment, two second sub-bias signal lines DVH2 and one second sub-reference signal line Vref12 are alternately arranged with a quantity ratio of 2:1. In one embodiment, the second sub-bias signal lines DVH2 and the second sub-reference signal line Vref12 are alternately arranged based on other quantity ratios, which is not limited in the present disclosure, depending on the situation.

It should be noted that in the present disclosure, one signal line 30 is arranged corresponding to the pixel circuits 20 arranged in one column, which indicates that the pixel circuits 20 arranged in one column at least partially overlap with one signal line 30 in the direction perpendicular to the plane where the substrate 10 is located. In one example, one second sub-bias signal line DVH2 and one second sub-reference signal line Vref12 are arranged corresponding to the pixel circuits 20 arranged in one column, which indicates that the pixel circuits 20 arranged in the column at least partially overlap with one second sub-bias signal line DVH2 in the direction perpendicular to the plane where the substrate 10 is located, and the pixel circuits 20 arranged in the column at least partially overlap with one second sub-reference signal line Vref12 in the direction perpendicular to the plane where the substrate 10 is located, which are not repeated herein.

As shown in FIG. 1, the display panel further includes the light-emitting element 40. The light-emitting element 40 includes the anode RE, the light-emitting layer (not shown), and the cathode (not shown) that are arranged in the direction away from the substrate 10. As shown in FIGS. 3 to 6, the pixel circuit 20 includes the anode initialization transistor T7, the signal line 30 includes the second reference signal line Vref2, and the anode initialization transistor T7 is electrically connected between the second reference signal line Vref2 and the anode RE of the light-emitting element 40.

As shown in FIGS. 5 and 6, the second reference signal line Vref2 includes a third sub-reference signal line Vref21 extending along the first direction X and arranged along the second direction Y, and a fourth sub-reference signal line Vref22 extending along the second direction Y and arranged along the first direction X. The third sub-reference signal line Vref21 is electrically connected to the fourth sub-reference signal line Vref22, thus forming the second reference signal line Vref2 with the grid structure, to reduce overall resistance of the second reference signal line Vref2, to reduce the power consumption of the second reference signal line Vref2 and improve the signal transmission stability of the second reference signal line Vref2, which is conducive to improving the display uniformity and other display effects of the display panel. In such case, the bias signal line DVH, the first reference signal line Vref1, and the second reference signal line Vref2 are insulated from each other to avoid signal crosstalk.

In an embodiment, the third sub-reference signal line Vref21 and the fourth sub-reference signal line Vref22 are arranged in different layers, that is, signal lines extending along different directions are arranged in different metal layers to reduce the difficulty of laying the signal lines in a same metal layer. In one example, as shown in FIGS. 5, 6, 7c, and 7f, the third sub-reference signal line Vref21 may be arranged in the metal layer MC, the fourth sub-reference signal line Vref22 may be arranged in the metal layer M2. The third sub-reference signal line Vref21 may be electrically connected to the fourth sub-reference signal line Vref22 through a via-hole between the metal layer MC and the metal layer M2.

Therefore, in some embodiments, the first sub-bias signal line DVH1 and the second sub-bias signal line DVH2 are arranged in different layers, the first sub-reference signal line Vref11 and the second sub-reference signal line Vref12 are arranged in different layers, and the third sub-reference signal line Vref21 and the fourth sub-reference signal line Vref22 are arranged in different layers, that is, the signal lines extending along different directions are arranged in different metal layers to reduce the difficulty of laying the signal lines in a same metal layer.

In an embodiment, the second sub-bias signal line DVH2, the second sub-reference signal line Vref12, and the fourth sub-reference signal line Vref22 are arranged in a same layer, that is, signal lines extending along a same direction (that is, the first direction X) may be arranged in a same metal layer, reducing the occupation of the film, which is conductive to achieving the light and thin display panel.

In one embodiment, as shown in FIGS. 5, 6, 7c, 7e, and 7f, the third sub-reference signal line Vref21 may be arranged in the metal layer MC, both the first sub-bias signal line DVH1 and the first sub-reference signal line Vref11 may be arranged in the metal layer MG, and the second sub-bias signal line DVH2, the second sub-reference signal line Vref12, and the fourth sub-reference signal line Vref22 may be arranged in the metal layer M2.

In an embodiment, as shown in FIGS. 5, 6, and 7f, the pixel circuits 20 are arranged in an array along the first direction X and the second direction Y. The second direction X is the column direction. The pixel circuits 20 are arranged in the columns N20. The number of the second sub-bias signal line DVH2 is N21. The number of the second sub-reference signal line Vref12 is N22. The number of the fourth sub-reference signal line Vref22 is N23. N21≤N20, N22≤N20, N23≤N20, and each of N20, N21, N22, and N23 represents a positive integer. That is, the pixel circuits 20 are arranged in the columns N20 as a reference, the number N21 of the second sub-bias signal line DVH2 may be equal to or less than the columns N20 of the pixel circuits 20, the number N22 of the second sub-reference signal lines Vref12 may be equal to or less than the columns N20 of the pixel circuits 20, and the number N23 of the fourth sub-reference signal lines Vref22 may also be equal to or less than the columns N20 of the pixel circuits 20.

In some embodiments, for the pixel circuits 20 arranged in each of the columns, one second sub-bias signal line DVH2, one second sub-reference signal line Vref12 and one fourth sub-reference signal line Vref22 may be arranged corresponding to the pixel circuits 20 arranged in the column. In such case, N21=N22=N23=N20. Such arrangement is conductive to increasing the number of the second sub-bias signal line DVH2, the number of the second sub-reference signal line Vref12, and the number of the fourth sub-reference signal line Vref22, and reducing resistance of the bias signal line DVH, resistance of the first reference signal line Vref1, and resistance of the second reference signal line Vref2, to reduce the power consumption of the bias signal line DVH, the power consumption of the first reference signal line Vref1, and the power consumption of the second reference signal line Vref2, and improve the signal transmission stability of the bias signal line DVH, the signal transmission stability of the first reference signal line Vref1 and the signal transmission stability of the second reference signal line Vref2.

In other embodiments, as shown in FIGS. 5, 6, and 7f, the second sub-bias signal line DVH2 is arranged corresponding to the pixel circuits 20 arranged in a part of the columns, the second sub-reference signal line Vref12 is arranged corresponding to the pixel circuits 20 arranged in another part of the columns, and the fourth sub-reference signal line Vref22 is arranged corresponding to the pixel circuits 20 arranged in another part of columns. In such case, N21<N20, N22<N20, and N23<N20. In such way, a layout density of the second sub-bias signal line DVH2, the second sub-reference signal line Vref12, and fourth sub-reference signal line Vref22 that extend along a same direction (that is, the second direction Y) is reduced, reducing a layout space of the pixel circuits 20 and increasing the pixel density of the display panel, which is conductive to achieving the high-resolution and high-definition display.

In an embodiment, N21+N22+N23≤N20. In some embodiments, as shown in FIGS. 5, 6, and 7f, one of the second sub-bias signal line DVH2, the second sub-reference signal line Vref12, and the fourth sub-reference signal line Vref22 is arranged corresponding to the pixel circuits 20 arranged in each of the columns, which indicates that a distinction is made based on the types of the second sub-bias signal line DVH2, the second sub-reference signal line Vref12, and the fourth sub-reference signal line Vref22. One of the second sub-bias signal line DVH2, the second sub-reference signal line Vref12, and the fourth sub-reference signal line Vref22 is arranged corresponding to the pixel circuits 20 arranged in each of the columns. Therefore, N21+N22+N23=N20. Such arrangement may relatively increase a distance between the second sub-bias signal line DVH2, the second sub-reference signal line Vref12, and the fourth sub-reference signal line Vref22, reducing the mutual influence between the three signal lines.

In other embodiments, for the pixel circuits 20 arranged in each of a part of the columns, one of the second sub-bias signal line DVH2, the second sub-reference signal line Vref12, and the fourth sub-reference signal line Vref22 may be arranged corresponding to the pixel circuits 20 arranged in the column. For the pixel circuits 20 arranged in each of the other columns, the second sub-bias signal line DVH2, the second sub-reference signal line Vref12, and the fourth sub-reference signal line Vref22 may not be arranged corresponding to the pixel circuits 20 arranged in the column, and signal lines for transmitting other signals may be arranged corresponding to the pixel circuits 20 arranged in the column. In such case, N21+N22+N23<N20. Such arrangement may meet the requirements of laying different functional signal lines within a limited film.

As shown in FIGS. 5, 6, and 7f, one of the second sub-bias signal line DVH2, the second sub-reference signal line Vref12, and the fourth sub-reference signal line Vref22 may be arranged corresponding to the pixel circuits 20 arranged in each of the columns. Based on this, the light-emitting element 40 includes a first color light-emitting element 41, a second color light-emitting element 42, and a third color light-emitting element 43. As shown in FIG. 9c, an anode RE41 of the first color light-emitting element 41 represents the first color light-emitting element 41, an anode RE42 of the second color light-emitting element 42 represents the second color light-emitting element 42, and an anode RE43 of the third color light-emitting element 43 represents the third color light-emitting element 43. It can be seen that in order to meet the display requirements, first color light-emitting elements 41 are arranged along the second direction, forming multiple columns, named as first light-emitting element columns 401; the second color light-emitting element 42 and the third color light-emitting element 43 are alternately arranged along the second direction Y, forming multiple columns, named as second light-emitting element columns 402. Moreover, the first light-emitting element columns 401 and the second light-emitting element columns 402 are alternately arranged along the first direction X. For two adjacent second light-emitting element columns 402 along the first direction X, the second color light-emitting elements 42 in one of the second light-emitting element columns 402 correspond to the third color light-emitting elements 43 in the other second light-emitting element column 402 along the first direction X; and the third color light-emitting elements 43 in one of the second light-emitting element columns 402 correspond to the second color light-emitting elements 42 in the other second light-emitting element column 402 along the first direction X. Therefore, light-emitting elements arranged in four columns including two first light-emitting element columns 401 and two second light-emitting element columns 402 arranged adjacent to each other along the first direction X form a pixel repeating unit.

Correspondingly, as shown in FIGS. 5 and 9c, for the pixel circuits 20 arranged in two adjacent columns, the pixel circuits 20 arranged in one of the columns drive the first color light-emitting elements 41, that is, the pixel circuits 20 arranged in the column drive the first light-emitting element column 401, and the pixel circuits 20 arranged in the other columns drive the second color light-emitting elements 42 and the third color light-emitting elements 43, that is, the pixel circuits 20 arranged in the other columns drive the second light-emitting element column 402. Since light-emitting elements arranged in four columns including two first light-emitting element columns 401 and two second light-emitting element columns 402 arranged adjacent to each other along the first direction X form the pixel repeating unit, the pixel circuits 20 arranged in four adjacent columns along the first direction X also form a pixel circuit repeating unit.

For the pixel circuits 20 arranged in the four adjacent columns, the second sub-bias signal line DVH2, the second sub-reference signal line Vref12, and the fourth sub-reference signal line Vref22 may be arranged corresponding to the pixel circuits 20 arranged in three of the four columns, respectively. One of the second sub-bias signal line DVH2, the second sub-reference signal line Vref12, and the fourth sub-reference signal line Vref22 may be arranged corresponding to the pixel circuits 20 arranged in the remaining one column. Therefore, for the pixel circuits 20 arranged in the four adjacent columns, one of the second sub-bias signal line DVH2, the second sub-reference signal line Vref12, and the fourth sub-reference signal line Vref22 is arranged corresponding to the pixel circuits 20 arranged in two of the four columns, and the other two of the second sub-bias signal line DVH2, the second sub-reference signal line Vref12, and the fourth sub-reference signal line Vref22 are arranged corresponding to the pixel circuits 20 arranged in the other two columns.

That is, a distinction is made based on the types of the second sub-bias signal line DVH2, the second sub-reference signal line Vref12, and the fourth sub-reference signal line Vref22. In some embodiments, as shown in FIGS. 5, 6, and 7f, for the pixel circuits 20 arranged in four adjacent columns, the fourth sub-reference signal line Vref22 is arranged corresponding to the pixel circuits 20 arranged in each of two of the four columns, the second sub-bias signal line DVH2 is arranged corresponding to the pixel circuits 20 arranged in one of the other two columns, and the second sub-reference signal line Vref12 is arranged corresponding to the pixel circuits 20 arranged in the other column.

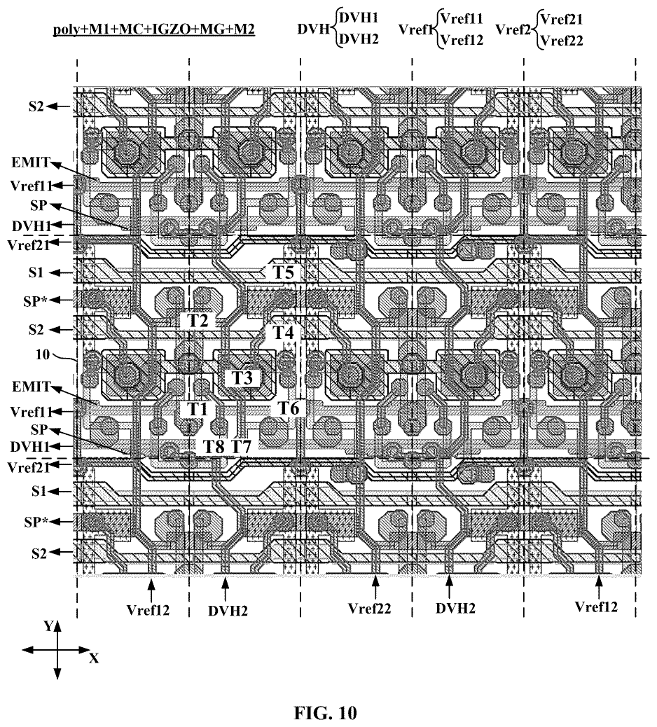

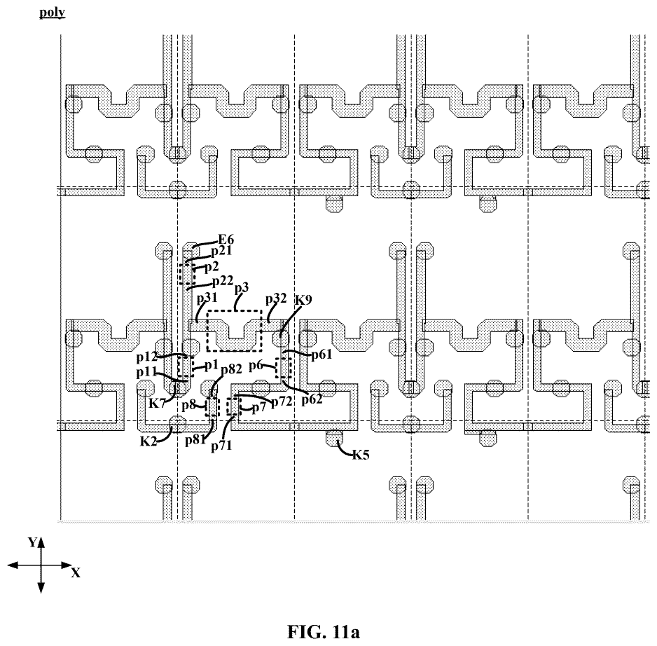

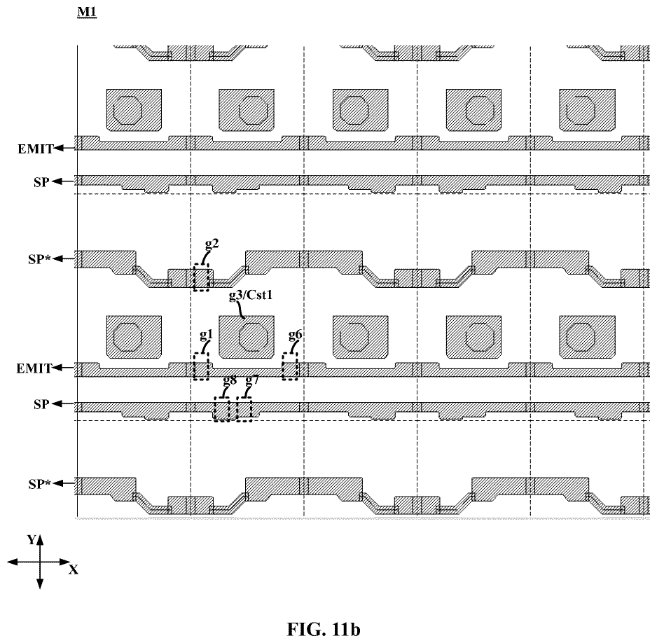

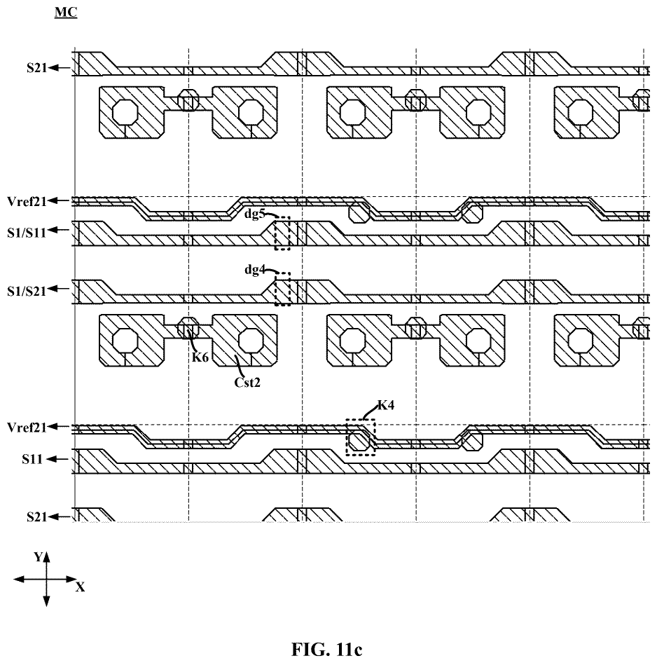

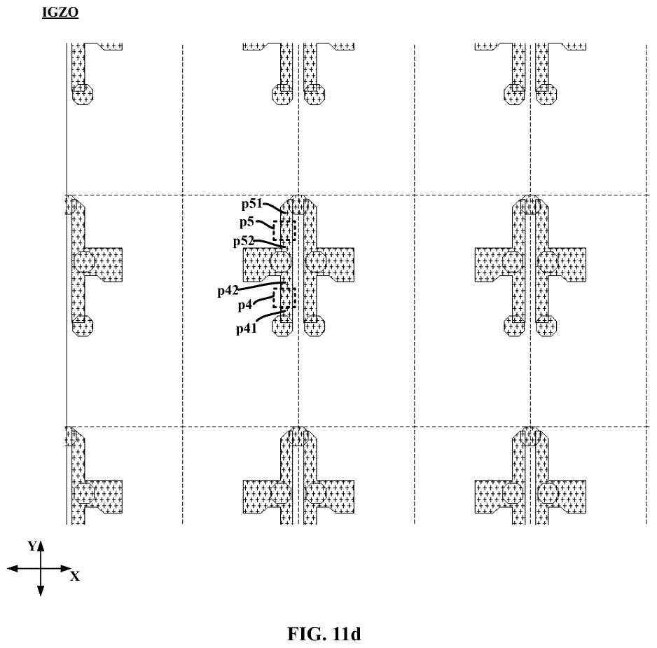

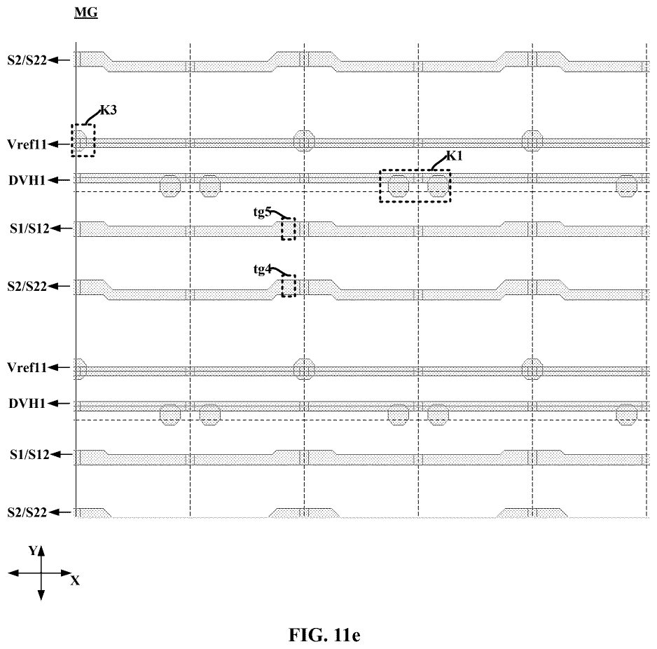

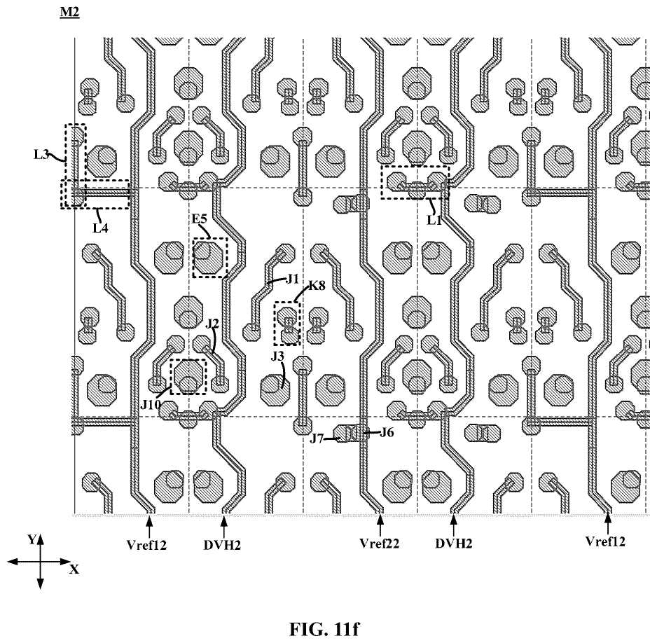

FIG. 10 is a schematic diagram of a partial layout structure of a display panel according to another embodiment of the present disclosure. The partial layout structure includes layout structures of the active layer poly, the metal layer M1, the metal layer MC, the metal layer MG, and the metal layer M2. For clarity, FIG. 11a is a schematic diagram of a layout structure of an active layer poly in the layout structure shown in FIG. 10, FIG. 11b is a schematic diagram of a layout structure of a metal layer M1 in the layout structure shown in FIG. 10, FIG. 11c is a schematic diagram of a layout structure of a metal layer MC in the layout structure shown in FIG. 10, FIG. 11d is a schematic diagram of a layout structure of an oxide layer IGZO in the layout structure shown in FIG. 10, FIG. 11e is a schematic diagram of a layout structure of a metal layer MG in the layout structure shown in FIG. 10, and FIG. 11f is a schematic diagram of a layout structure of a metal layer M2 in the layout structure shown in FIG. 10.

It can be seen that a distinction is made based on the types of the second sub-bias signal line DVH2, the second sub-reference signal line Vref12, and the fourth sub-reference signal line Vref22. In other embodiments, as shown in FIGS. 10 and 11f, for the pixel circuits 20 arranged in four adjacent columns, the second sub-bias signal line DVH2 is arranged corresponding to the pixel circuits 20 arranged in each of two of the four columns, the second sub-reference signal line Vref12 is arranged corresponding to the pixel circuits 20 arranged in one of the other two columns, and the fourth sub-reference signal line Vref22 is arranged corresponding to the pixel circuits 20 arranged in the other column.

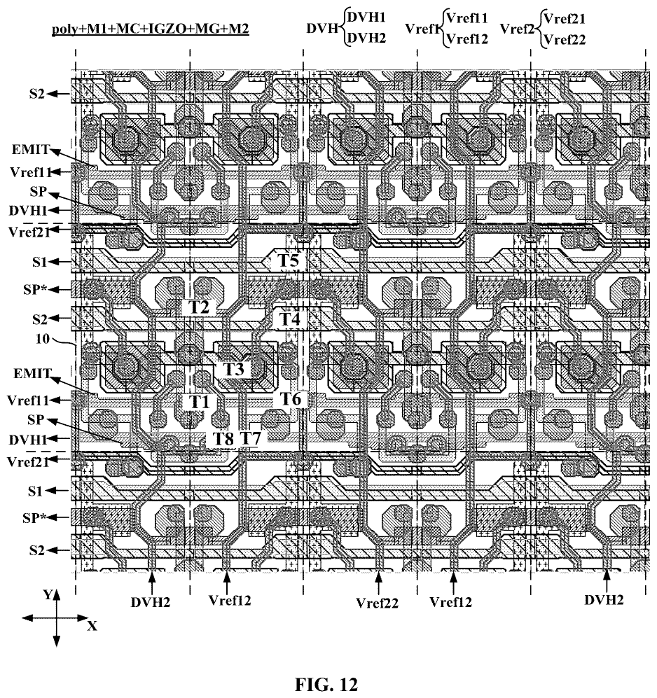

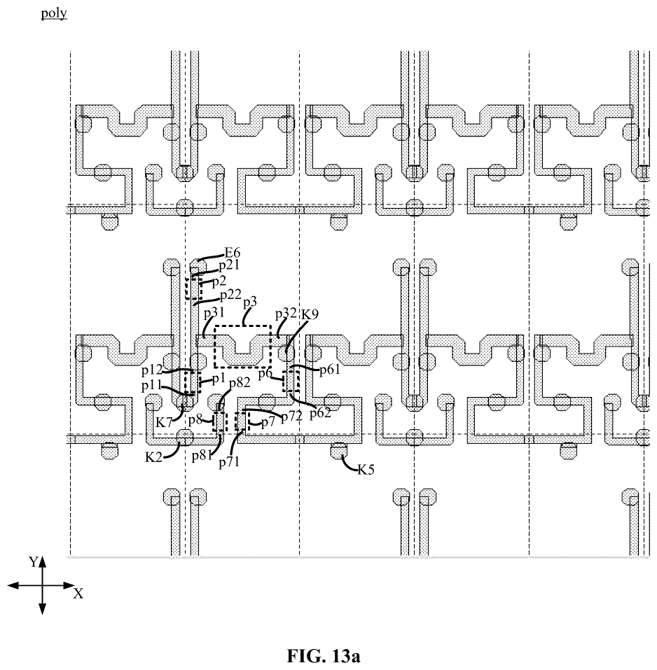

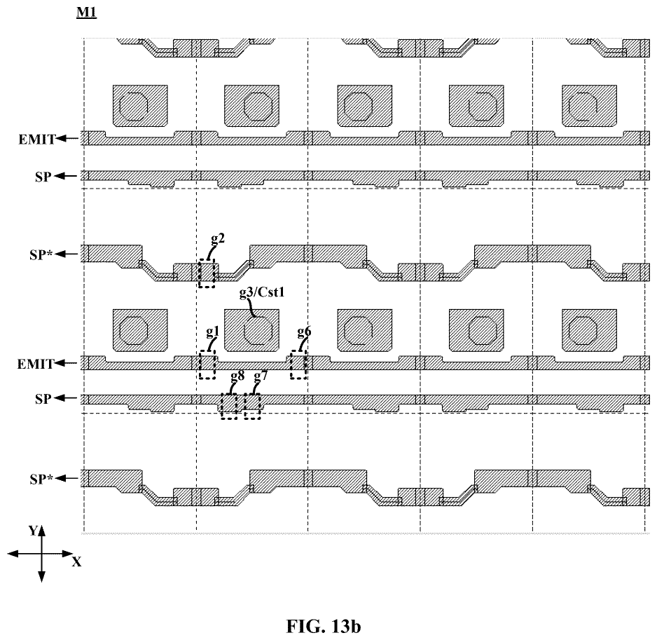

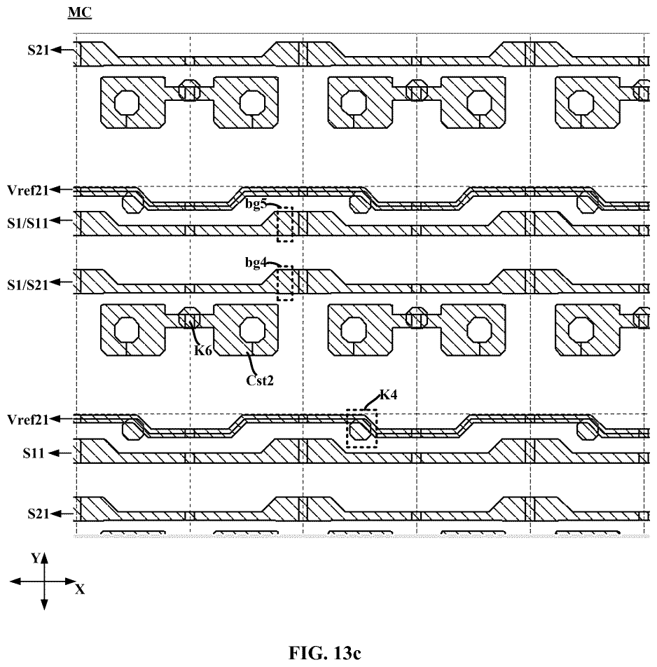

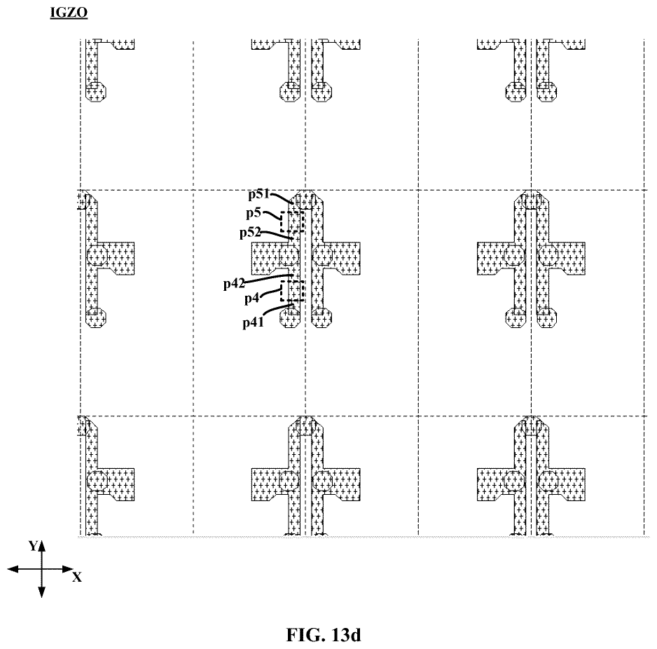

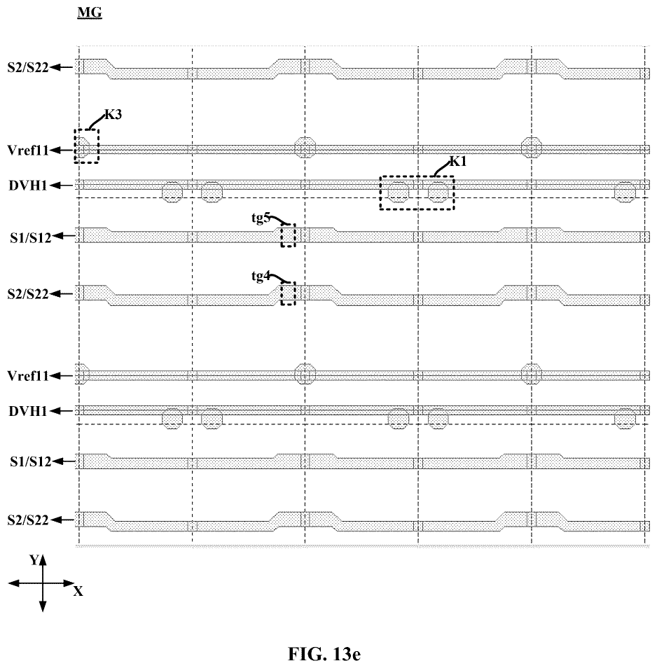

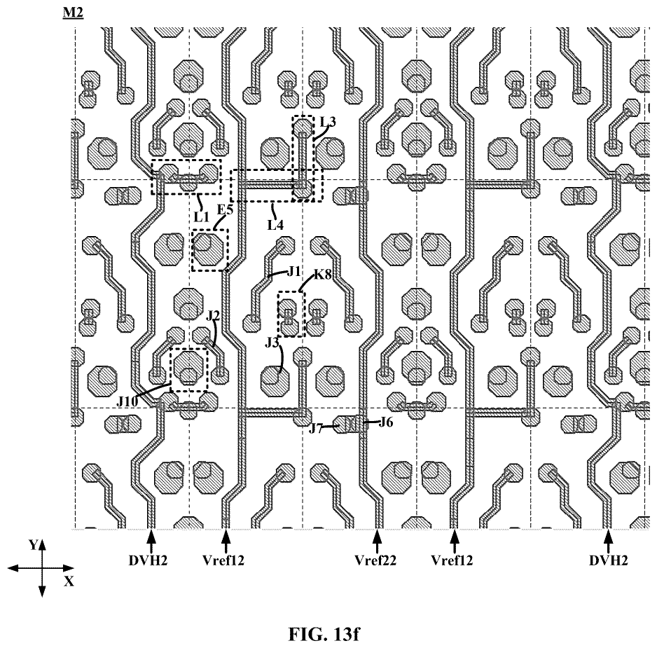

FIG. 12 is a schematic diagram of a partial layout structure of a display panel according to another embodiment of the present disclosure. The partial layout structure includes layout structures of the active layer poly, the metal layer M1, the metal layer MC, the metal layer MG, and the metal layer M2. For clarity, FIG. 13a is a schematic diagram of a layout structure of an active layer poly in the layout structure shown in FIG. 12, FIG. 13b is a schematic diagram of a layout structure of a metal layer M1 in the layout structure shown in FIG. 12, FIG. 13c is a schematic diagram of a layout structure of a metal layer MC in the layout structure shown in FIG. 12, FIG. 13d is a schematic diagram of a layout structure of an oxide layer IGZO in the layout structure shown in FIG. 12, FIG. 13e is a schematic diagram of a layout structure of a metal layer MG in the layout structure shown in FIG. 12, and FIG. 13f is a schematic diagram of a layout structure of a metal layer M2 in the layout structure shown in FIG. 12.

It can be seen that a distinction is made based on the types of the second sub-bias signal line DVH2, the second sub-reference signal line Vref12, and the fourth sub-reference signal line Vref22. In other embodiments, as shown in FIGS. 12 and 13f, for the pixel circuits 20 arranged in four adjacent columns, the second sub-reference signal line Vref12 is arranged corresponding to the pixel circuits 20 arranged in each of two of the four columns, the second sub-bias signal line DVH2 is arranged corresponding to the pixel circuits 20 arranged in one of the other two columns, and the fourth sub-reference signal line Vref22 is arranged corresponding to the pixel circuits 20 arranged in the other column.

Furthermore, in an embodiment, in the pixel circuits 20 arranged in four adjacent columns, the pixel circuits 20 arranged in two of the four columns corresponding to one of the second sub-bias signal line DVH2, the second sub-reference signal line Vref12, and the fourth sub-reference signal line Vref22 are arranged with an intervening column, and the pixel circuits 20 arranged in the other two columns corresponding to the other two of the second sub-bias signal line DVH2, the second sub-reference signal line Vref12, and the fourth sub-reference signal line Vref22 are also arranged with an intervening column.

In some embodiments, as shown in FIGS. 5, 6, and 7f, for the pixel circuits 20 arranged in the four adjacent columns, the fourth sub-reference signal line Vref22 is arranged corresponding to the pixel circuits 20 arranged in each of two of the four columns, and the second sub-bias signal line DVH2 and the second sub-reference signal line Vref12 are arranged corresponding to the pixel circuits 20 arranged in the other two columns, respectively. Moreover, the pixel circuits 20 arranged in the two columns corresponding to the fourth sub-reference signal line Vref22 are arranged with an intervening column. Therefore, the pixel circuits 20 arranged in the two columns corresponding to the second sub-bias signal line DVH2 and the second sub-reference signal line Vref12 are arranged with an intervening column.

In some embodiments, as shown in FIGS. 10 and 11f, for the pixel circuits 20 arranged in the four adjacent columns, the second sub-bias signal line DVH2 is arranged corresponding to the pixel circuits 20 arranged in each of two of the four columns, and the second sub-reference signal line Vref12 and the fourth sub-reference signal line Vref22 are arranged corresponding to the pixel circuits 20 arranged in the other two columns, respectively. Moreover, the pixel circuits 20 arranged in the two columns corresponding to the second sub-bias signal line DVH2 are arranged with an intervening column. Therefore, the pixel circuits 20 arranged in the two columns corresponding to the second sub-reference signal line Vref12 and the fourth sub-reference signal line Vref22 are also arranged with an intervening column.

In some embodiments, as shown in FIGS. 12 and 13f, for the pixel circuits 20 arranged in the four adjacent columns, the second sub-reference signal line Vref12 is arranged corresponding to the pixel circuits 20 arranged in each of two of the four columns, and the second sub-bias signal line DVH2 and the fourth sub-reference signal line Vref22 are arranged corresponding to the pixel circuits 20 arranged in the other two columns, respectively. Moreover, the pixel circuits 20 arranged in the two columns corresponding to the second sub-reference signal line Vref12 are arranged with an intervening column. Therefore, the pixel circuits 20 arranged in the two columns corresponding to the second sub-bias signal line DVH2 and the fourth sub-reference signal line Vref22 are arranged with an intervening column.

Furthermore, in an embodiment, for the pixel circuits 20 arranged in the four adjacent columns, the pixel circuits 20 arranged in two of the four columns corresponding to one of the second sub-bias signal line DVH2, the second sub-reference signal line Vref12, and the fourth sub-reference signal line Vref22 drive the first color light-emitting element 41.

As described above, light-emitting elements arranged in four columns including two first light-emitting element columns 401 and two second light-emitting element columns 402 arranged adjacent to each other along the first direction X form the pixel repeating unit. In addition, in one pixel repeating unit, two first light-emitting element columns 401 (including the first color light-emitting elements 41 arranged along the second direction Y) are arranged in a same manner. Therefore, for the pixel circuits 20 arranged in the four adjacent columns, the pixel circuits 20 arranged in two of the four columns corresponding to one of the second sub-bias signal line DVH2, the second sub-reference signal line Vref12, and the fourth sub-reference signal line Vref22 drive the corresponding first color light-emitting elements 41, and pixel columns formed by the first color light-emitting elements 41 and the pixel circuits 20 for driving the first color light-emitting elements 41 have the same layout design, greatly reducing the difficulty of layout design.

In one embodiment, in some embodiments, as shown in FIGS. 5, 6, and 7f, for the pixel circuits 20 arranged in the four adjacent columns, the pixel circuits 20 arranged in two of the four columns corresponding to the fourth sub-reference signal line Vref22 drive the corresponding first color light-emitting elements 41, and the pixel circuits 20 arranged in the other two columns corresponding to the second sub-bias signal line DVH2 and the second sub-reference signal line Vref12 respectively drive the corresponding second color light-emitting elements 42 and the corresponding third color light-emitting elements 43.

In other embodiments, as shown in FIGS. 10 and 11f, for the pixel circuits 20 arranged in the four adjacent columns, the pixel circuits 20 arranged in two of the four columns corresponding to the second sub-bias signal line DVH2 drive the corresponding first color light-emitting elements 41, and the pixel circuits 20 arranged in the other two columns corresponding to the second sub-reference signal line Vref12 and the fourth sub-reference signal line Vref22 respectively drive the corresponding second color light-emitting elements 42 and the corresponding third color light-emitting elements 43.

In other embodiments, as shown in FIGS. 12 and 13f, for the pixel circuits 20 arranged in the four adjacent columns, the pixel circuits 20 arranged in two of the four columns corresponding to the second sub-reference signal line Vref12 drive the corresponding first color light-emitting elements 41, and the pixel circuits 20 arranged in the other two columns corresponding to the second sub-bias signal line DVH2 and the fourth sub-reference signal line Vref22 respectively drive the corresponding second color light-emitting elements 42 and the corresponding third color light-emitting elements 43.

In an embodiment, the first color light-emitting element 41 is a green light-emitting element, the second color light-emitting element 42 is a red light-emitting element, and the third color light-emitting element 43 is a blue light-emitting element.

In the above embodiments, the pixel circuits 20 are arranged in the columns N20 as a reference, the number N21 of the second sub-bias signal line DVH2 may be equal to or less than the columns N20 of the pixel circuits 20, the number N22 of the second sub-reference signal line Vref12 may be equal to or less than the columns N20 of the pixel circuits 20, and the number N23 of the fourth sub-reference signal line Vref22 may be equal to or less than the columns N20 of the pixel circuits 20. In order to ensure that each of the pixel circuits 20 is electrically connected to the bias signal line DVH, the first reference signal line Vref1, and the second reference signal line Vref2, one first sub-bias signal line DVH1, one first sub-reference signal line Vref11, and one third sub-reference signal line Vref21 are arranged corresponding to the pixel circuits 20 arranged in each of the rows, as shown in FIGS. 5, 6, 7e, 10 and 11e, 12 and 13e. That is, the pixel circuits 20 are arranged in the rows N10 as a reference, the number N11 of the first sub-bias signal line DVH1, the number N12 of the first sub-reference signal line Vref11, and the number N13 of the third sub-reference signal line Vref21 meet: N11=N12=N13=N10.

On basis of this, the following description illustrates how the sub-bias signal lines extending along different directions in the bias signal line DVH are electrically connected, and the sub-bias signal lines are electrically connected to corresponding thin film transistors in the pixel circuit 20.

As shown in FIGS. 5, 6, 7a, 7e, 7f, 10, 11a, 11e, 11f, 12, 13a, 13e, and 13f, the display panel further includes multiple first connection portions L1 arranged in an array along the first direction X and the second direction Y. Each of the multiple first connection portions L1 extends along the first direction X. The first connection portion L1 and the first sub-bias signal line DVH1 are arranged in different layers. In an embodiment, the first connection portion L1 is arranged in the metal layer M2, and the first sub-bias signal lines DVH1 is arranged in the metal layer MG. The first sub-bias signal line DVH1 is electrically connected to the bias transistor T8 through the first connection portion L1. In one embodiment, the first sub-bias signal line DVH1 arranged in the metal layer MG is electrically connected to the first electrode p81 of the bias transistor T8 through the connection portion K1 arranged in the metal layer MG, the first connection portion L1 arranged in the metal layer M2, and a connection portion K2 arranged in the active layer poly.

As shown in FIGS. 5, 6, 7a, 7e, and 7f, the second sub-bias signal line DVH2 may further include a second connection portion L2 extending along the first direction X. The second connection portion L2 is electrically connected to the first connection portion L1 in the same layer, that is, both the second connection portion L2 and the first connection portion L2 may be arranged in the metal layer M2 and electrically connected to each other. The second sub-bias signal line DVH2 is electrically connected to the bias transistor T8 through the second connection portion L2 and the first connection portion L1. In one embodiment, the second sub-bias signal line DVH2 arranged in the metal layer M2 is electrically connected to the first electrode p81 of the bias transistor T8 through the second connection portion L2 and the first connection portion L1 arranged in the metal layer M2, and the connection portion K2 arranged in the active layer poly. The second sub-bias signal line DVH2 arranged in the metal layer M2 is electrically connected to the first sub-bias signal line DVH1 arranged in the metal layer MG through the second connection portion L2 arranged in the metal layer M2 and the connection portion K1 arranged in the metal layer MG.

As shown in FIGS. 10, 11a, 11e, 11f, 12, 13a, 13e, and 13f, the second sub-bias signal line DVH2 arranged in the metal layer M2 may further be electrically connected to the first sub-bias signal line DVH1 arranged in the metal layer MG at an overlapping position of the second sub-bias signal line DVH2 and the first sub-bias signal line DVH1 in the direction perpendicular to the plane where the substrate 10 is located. In addition, the second sub-bias signal line DVH2 arranged in the metal layer M2 and the first sub-bias signal line DVH1 arranged in the metal layer MG may further be electrically connected to the first electrode p81 of the bias transistor T8 through the first connection portion L1 arranged in the metal layer M2 and the connection portion K2 arranged in the active layer poly.

The following description illustrates how the sub-reference signal lines extending along different directions in the first reference signal line Vref1 are electrically connected, and the sub-reference signal lines are electrically connected to corresponding thin film transistors in the pixel circuit 20.

As shown in FIGS. 5, 6, 7d to 7f, 10, 11d to 11f, 12, and 13d to 13f, the display panel further includes multiple third connection portions L3 arranged in an array along the first direction X and the second direction Y. Each of the multiple third connection portions L3 extends along the second direction Y. The third connection portion L3 and the first sub-reference signal line Vref11 are arranged in different layers. In an embodiment, the third connection portion L2 is arranged in the metal layer M2, and the first sub-reference signal line Vref11 is arranged in the metal layer MG. The first sub-reference signal line Vref11 is electrically connected to the gate initialization transistor T5 through the third connection portion L3. In one embodiment, the first sub-reference signal line Vref11 arranged in the metal layer MG is electrically connected to the first electrode p51 of the gate initialization transistor T5 through the connection portion K3 arranged in the metal layer MG and the third connection portion L3 arranged in the metal layer M2.

As shown in FIGS. 5, 6, 7d to 7f, 10, 11d to 11f, 12, and 13d to 13f, the second sub-reference signal line Vref12 further includes a fourth connection portion L4 extending along the first direction X. The fourth connection portion L4 is electrically connected to the third connection portion L3 in a same layer, that is, both the fourth connection portion L4 and the third connection portion L3 may be arranged in the metal layer M2 and electrically connected to each other. The second sub-reference signal line Vref12 is electrically connected to the anode initialization transistor T5 through the fourth connection portion L4. In one embodiment, the second sub-reference signal line Vref12 arranged in the metal layer M2 is electrically connected to the first electrode p51 of the gate initialization transistor T5 through the fourth connection portion L4 arranged in the metal layer M2. In addition, the second sub-reference signal line Vref12 arranged in the metal layer M2 is electrically connected to the first sub-reference signal line Vref11 arranged in the metal layer MG through the fourth connection portion L4 and the third connection portion L3 arranged in the metal layer M2, and the connection portion K3 arranged in the metal layer MG.

The following description illustrates how the sub-reference signal lines extending along different directions in the second reference signal line Vref2 are electrically connected, and the sub-reference signal lines are electrically connected to corresponding thin film transistors in the pixel circuit 20.

As shown in FIGS. 5, 6, 7a, 7c, 7f, 10, 11a, 11c, 11f, 12, 13a, 13c, and 13f, in the direction perpendicular to the plane where the substrate 10 is located, the third sub-reference signal line Vref21 is electrically connected to the fourth sub-reference signal line Vref22 at an overlapping position of the third sub-reference signal line Vref21 and the fourth sub-reference signal line Vref22. In one embodiment, the third sub-reference signal line Vref21 arranged in the metal layer MC is electrically connected to the fourth sub-reference signal line Vref22 arranged in the metal layer M2 through a connection portion J6 arranged in the metal layer M2 and a connection portion K4 arranged in the metal layer MC at the overlapping position. In addition, the third sub-reference signal line Vref21 arranged in the metal layer MC is electrically connected to the first electrode p71 of the anode initialization transistor T7 through the connection portion K4 arranged in the metal layer MC, the connection portion J6 and the connection portion J7 arranged in the metal layer M2, and a connection portion K5 arranged in the active layer poly. In addition, the fourth sub-reference signal line Vref22 arranged in the metal layer M2 is also electrically connected to the first electrode p71 of the anode initialization transistor T7 through the connection portion J7 arranged in the metal layer M2, and the connection portion K5 arranged in the active layer poly.

It should be noted that a difference in the three layout structures of FIG. 5, FIG. 10, and FIG. 12 is only that the second sub-bias signal line DVH2, the second sub-reference signal line Vref12, and the fourth sub-reference signal line Vref22, which extend along the second direction Y, are arranged along the first direction X in different sequences. The connection manner of the signal lines is adjusted accordingly. The layout structure shown in FIG. 5 is illustrated as an example. Each of the embodiments is also suitable for the layout structures shown in FIGS. 10 and 12, which is not repeated.

As shown in FIGS. 3 to 6, and 8, the pixel circuit 20 further includes the first light-emitting control transistor T1, the signal line 30 further includes the first power signal line PVDD, and the first light-emitting control transistor T1 is electrically connected between the first power signal line PVDD and the first electrode of the driving transistor T3.

As shown in FIGS. 5, 6, 7a, and 7b, the first light-emitting control transistor T1 includes the channel region p1 arranged in the active layer poly, the first electrode p11 and the second electrode p12 that are connected to the channel region p1. The second electrode p12 of the first light-emitting control transistor T1 is directly electrically connected to the first electrode p31 of the driving transistor T3 in the active layer poly.

As shown in FIGS. 8, 9a, and 9b, the first power signal line PVDD includes a first sub-power signal line PVDD1 extending along the first direction X and arranged along the second direction Y, and a second sub-power signal line PVDD2 extending along the second direction Y and arranged along the first direction X. The first sub-power signal line PVDD1 is electrically connected to the second sub-power signal line PVDD2, thus forming the first power signal line PVDD with the grid structure, to reduce overall resistance of the first power signal line PVDD, to reduce the power consumption of the first power signal line PVDD, and improve the signal transmission stability of the first power signal line PVDD, which is conducive to improving the display uniformity and other display effects of the display panel. In such case, the bias signal line DVH, the first reference signal line Vref1, the second reference signal line Vref2 and the first power signal line PVDD are insulated from each other to avoid signal crosstalk.

In an embodiment, the first sub-power signal line PVDD1 and the second sub-power signal line PVDD2 are arranged in different layers, that is, signal lines extending along different directions are arranged in different metal layers to reduce the difficulty of laying the signal lines in a same metal layer. In one example, as shown in FIGS. 8, 9a, and 9b, the first sub-power signal line PVDD1 is arranged in the metal layer M3. The second sub-power signal line PVDD2 is arranged in the metal layer M4. The first sub-power signal line PVDD1 may be electrically connected to the second sub-power signal line PVDD2 through a via-hole between the metal layer M3 and the metal layer M4.

Therefore, in some embodiments, the first sub-bias signal line DVH1 and the second sub-bias signal line DVH2 are arranged in different layers, the first sub-reference signal line Vref11 and the second sub-reference signal line Vref12 are arranged in different layers, the third sub-reference signal line Vref21 and the fourth sub-reference signal line Vref22 are arranged in different layers, and the first sub-power signal line PVDD1 and the second sub-power signal line PVDD2 are arranged in different layers, that is, signal lines extending along different directions are arranged in different metal layers, to reduce the difficulty of laying the signal lines in a same metal layer.

In an embodiment, as shown in FIG. 1, the display panel includes the substrate 10 and the first metal layer MC, the second metal layer MG, a third metal layer M2, a fourth metal layer M3, and a fifth metal layer M5 that are arranged in the direction away from the substrate 10. As shown in FIG. 7c, the third sub-reference signal line Vref21 is arranged in the first metal layer MC. As shown in FIG. 7e, the first sub-bias signal line DVH1 and the first sub-reference signal line Vref11 are arranged in the second metal layer MG. As shown in FIG. 7f, the second sub-bias signal line DVH2, the second sub-reference signal line Vref12, and the fourth sub-reference signal line Vref22 are arranged in the third metal layer M2. As shown in FIG. 9a, the first sub-power signal line PVDD1 is arranged in the fourth metal layer M3. As shown in FIG. 9b, the second sub-power signal line PVDD2 is arranged in the fifth metal layer M4.

As shown in FIG. 9a, the first sub-power signal line PVDD1 includes a first sub-segment D1 and a second sub-segment D2 that are alternately connected along the first direction X. A width of the second sub-segment D2 along the second direction Y is greater than a width of the first sub-segment D1 along the second direction Y, and a sum of a length of the first sub-segment D1 and a length of the second sub-segment D2 adjacent to the first sub-segment D1 along the first direction X is greater than a length of the pixel circuit 20 along the first direction X.

It should be noted that the first sub-power signal line PVDD1 is actually an entire signal line extending along the first direction X, and the first sub-power signal line PVDD1 has a width and a shape that vary with a position in the first direction X. In the present disclosure, for the sake of convenience in description, the first sub-power signal line PVDD1 is divided into the first sub-segment D1 and the second sub-segment D2, which is not intended to limit the first sub-power signal line PVDD1.

As shown in FIGS. 8, 9a and 9b, the first sub-segment D1 and the second sub-segment D2 are electrically connected to the second sub-power signal line PVDD2 at a connection position of the first sub-segment D1 and the second sub-segment D2. In one embodiment, the first sub-segment D1 and the second sub-segment D2 that are arranged in the metal layer M3 are connected to the second sub-power signal line PVDD2 arranged in the metal layer M4 sequentially through the connection portion J8 arranged in the metal layer M3 and the connection portion J9 arranged in the metal layer M4 at the connection position of the first sub-segment D1 and the second sub-segment D2.

As shown in FIGS. 8 and 9a, the first sub-power signal line PVDD1 further includes a fifth connection portion L5 extending along the second direction Y. The fifth connection portion L5 and the first sub-segment D1 are electrically connected to each other and arranged in a same layer, that is, the fifth connection portion L5 may also be arranged in the metal layer M3 and connected to the first sub-segment D1 in the same layer. As shown in FIGS. 5, 6, 7a, 7c, 7f, 8 and 9a, the fifth connection portion L5 is electrically connected to the first electrode p11 of the first light-emitting control transistor T1 sequentially through the connection portion J10 arranged in the metal layer M2, the connection portion K6 arranged in the metal layer MC, and the connection portion K7 arranged in the active layer poly. Moreover, as shown in FIGS. 5, 6, 7a to 7c, 7f, 8 and 9a, the fifth connection portion L5 is connected to an electrode plate Cst2 (that is arranged in the metal layer MC) of the storage capacitor Cst sequentially through the connection portion J10 arranged in the metal layer M2 and the connection portion K6 arranged in the metal layer MC. The other electrode plate Cst1 of the storage capacitor Cst is arranged in the metal layer M1 and also serves as the gate g3 of the driving transistor T3.

As shown in FIGS. 8 and 9b, the second sub-power signal line PVDD2 includes a third sub-segment D3 and a fourth sub-segment D4 that are alternately connected to each other along the second direction Y. A width of the fourth sub-segment D4 along the first direction X is greater than a width of the third sub-segment D3 along the first direction X. Two adjacent fourth sub-segments D4 are connected to each other through two third sub-segments D3 symmetrically arranged along the second direction Y. In addition, a sum of a length of the third sub-segment D3 and a length of the fourth sub-segments D4 adjacent to the third sub-segment D3 along the second direction Y is greater than or equal to a length of the pixel circuit 20 along the second direction Y.

As shown in FIGS. 8 and 9b, the signal line 30 further includes the data signal line DL extending along the second direction Y. In an embodiment, a width of the data signal line DL along the first direction X serves as a reference, the width of the fourth sub-segment D4 along the first direction X may be greater than twice the width of the data signal line DL along the first direction X, and the width of the third sub-segment D3 along the first direction X may be less than twice the width of the data signal line DL along the first direction X.

It should be noted that the second sub-power signal line PVDD2 is actually an entire signal line extending along the second direction Y, the second sub-power signal line PVDD2 has a width and a shape that vary with a position in the first direction X. In the present disclosure, for the sake of convenience in description, the second sub-power signal line PVDD2 is divided into the third sub-segment D3 and the fourth sub-segment D4, which is not intended to limit the second sub-power signal line PVDD2.

As shown in FIGS. 8, 9a, and 9b, the second sub-segment D2 at least partially overlaps with the fourth sub-segment D4 in the direction perpendicular to the plane where the substrate 10 is located. The second sub-segment D2 is a sub-segment with a larger width in the first sub-power signal line PVDD1 along the second direction Y, and the fourth sub-segment D4 is a sub-segment with a larger width in the second sub-power signal line PVDD2 along the first direction X. Therefore, the second sub-segment D2 is arranged to at least partially overlap with the fourth sub-segment D4 in the direction perpendicular to the plane where the substrate 10 is located, and the first sub-power signal line PVDD1 overlaps with the second sub-power signal line PVDD2 in a wide region, to reduce an area of light blocking, and improve a light transmittance, which is conductive to improving the display effect of the display panel. As shown in FIGS. 3 to 6, the pixel circuit 20 further includes the compensation transistor T4. The compensation transistor T4 is electrically connected between the gate of the driving transistor T3 and the second electrode of the driving transistor T3.

In an embodiment, the compensation transistor T4 may be an oxide thin film transistor, that is, an IGZO thin film transistor. As shown in FIGS. 5, 6, and 7b to 7f, the compensation transistor T4 includes a channel region p4 arranged in the oxide layer IGZO, a first electrode p41 and a second electrode p42 that are connected to the channel region p4. The first electrode p41 of the compensation transistor T4 is electrically connected to the second electrode p32 of the driving transistor T3 sequentially through a connection portion K8 arranged in the metal layer M2 and a connection portion K9 arranged in the active layer poly. The second electrode p42 of the compensation transistor T4 is directly electrically connected to the second electrode p52 of the gate initialization transistor T5 in the oxide layer IGZO, and is electrically connected to the gate g3 of the driving transistor T3 through the connection portion J1 arranged in the metal layer M2 and through a via-hole in the electrode plate Cst2 of the storage capacitor Cst arranged in the metal layer MC

As shown in FIGS. 5, 6, and 7c to 7e, the signal line 30 further includes the second scanning signal line S2 extending along the first direction X. The second scanning signal line S2 includes a third sub-scanning signal line S21 and a fourth sub-scanning signal line S22 that transmit a same scanning signal. The third sub-scanning signal line S21 is arranged in the metal layer MC and extends along the first direction X. The fourth sub-scanning signal line S22 is arranged in the metal layer MG and extends along the first direction X. In the direction perpendicular to the plane where the substrate 10 is located, the third sub-scanning signal line S21, the fourth sub-scanning signal line S22, and the channel region p4 of the compensation transistor T4 overlap with each other. In an embodiment, in the direction perpendicular to the plane where the substrate 10 is located, an overlapping part of the oxide layer IGZO with the third sub-scanning signal line S21 and the fourth sub-scanning signal line S22 is the channel region p4 of the compensation transistor T4, and a part of the third sub-scanning signal line S21 facing the channel region p4 of the compensation transistor T4 is a bottom gate bg4 of the compensation transistor T4, and the bottom gate bg4 of the compensation transistor T4 is electrically connected to the third sub-scanning signal line S21. A part of the fourth sub-scanning signal line S22 facing the channel region p4 of the compensation transistor T4 is a top gate tg4 of the compensation transistor T4, and the top gate tg4 of the compensation transistor T4 is electrically connected to the fourth sub-scanning signal line S22. Therefore, both the top gate tg4 and the bottom gate bg4 of the compensation transistor T4 are electrically connected to the second scanning signal line S2 for receiving a same scanning signal.

As shown in FIGS. 5, 6, 7d, 8, 9a and 9b, in the direction perpendicular to the plane where the substrate 10 is located, an overlapping region of the second sub-segment D2 with the fourth sub-segment D4 covers the compensation transistor T4 and the gate initialization transistor T5. In this way, the second sub-segment D2 and the fourth sub-segment D4 may block external light in the direction perpendicular to the plane where the substrate 10 is located, preventing external light from shining on the compensation transistor T4 and the gate initialization transistor T5, and avoiding affecting the performance of the compensation transistor T4 and the performance of the gate initialization transistor T5. Especially, when the compensation transistor T4 and the gate initialization transistor T5 are the IGZO thin film transistors, the performance stability of the compensation transistor T4 and the performance stability of the gate initialization transistor T5 can be improved.

As shown in FIGS. 5, 6, and 7b to 7f, the pixel circuit further includes a sixth connection portion J1. The sixth connection portion J1 is electrically connected between the gate initialization transistor T5 and the gate g3 of the driving transistor T3, and electrically connected between the compensation transistor T4 and the gate g3 of the driving transistor T3. The second electrode p42 of the compensation transistor T4 and the second electrode p52 of the gate initialization transistor T5 are both electrically connected to the gate g3 of the driving transistor T3 through the sixth connection portion J1 arranged in the metal layer M2 and through a via-hole in the electrode plate Cst2 of the storage capacitor Cst arranged in the metal layer MC. It can be seen from the schematic structural diagram of the pixel circuit 20 shown in FIGS. 3 and 4 that the sixth connection portion J1 corresponds to the first node N1.

As shown in FIGS. 5, 6, 7f, 8, 9a and 9b, in the direction perpendicular to the plane where the substrate 10 is located, each of the first sub-power signal line PVDD1 and the second sub-power signal line PVDD2 covers the sixth connection portion J1 to maintain stability of a potential of the first node N1, that is, to maintain the stability of a potential of the gate g3 of the driving transistor T3, which is conductive to improving the display effect of the display panel.

As shown in FIGS. 8 and 9b, the pixel circuits 20 are arranged in an array along the first direction X and the second direction Y. The signal line 30 further includes the data signal line DL extending along the second direction Y. The pixel circuits 20 arranged in one column are electrically connected to one data signal line DL. In an embodiment, the data signal line DL may be arranged in the metal layer M4.

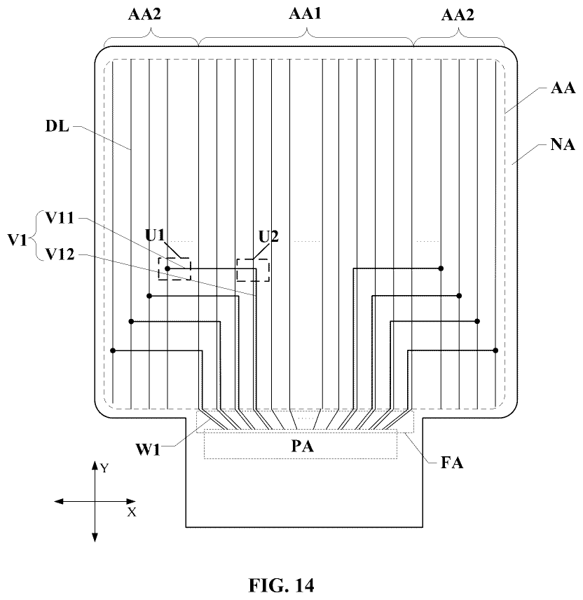

FIG. 14 is a schematic top view of a display panel according to another embodiment of the present disclosure. As shown in FIG. 14, the display panel further includes a display region AA and a non-display region NA at least partially surrounding the display region AA. The non-display region NA includes a fan-out region FA arranged on a side of the display region AA along the second direction Y. The fan-out region FA includes multiple fan-out lines W1.

The display region AA includes a first display region AA1 and a second display region AA2 arranged on at least one side of the first display region AA1 along the first direction X. Each of the first display region AA1 and the second display region AA2 includes multiple data signal lines DL. The multiple data signal lines DL are electrically connected to the fan-out lines W1. The multiple data signal lines DL in the second display region AA2 are electrically connected to the fan-out lines W1 through a connection line V1.

The connection line V1 is arranged in the display region AA, and includes a first connection segment V11 extending along the first direction X and a second connection segment V12 extending along the second direction Y. The second connection segment V12 is electrically connected to the fan-out lines W1, and the first connection segment V11 is electrically connected to the data signal lines DL in the second display region AA2.

As shown in FIG. 14, the data signal line DL in the first display region AA1 directly extends to a position in the fan-out region FA and is electrically connected to the fan-out line W1 in the fan-out region FA. The data signal line DL in the second display region AA2 is electrically connected to the fan-out line W1 in the fan-out region FA through the connection line V1 arranged in the display region AA. In one embodiment, the data signal line DL in the second display region AA2 is connected to the fan-out line W1 in the fan-out region FA first through the first connection segment V11 extending along the first direction X, and then through the second connection segment V12 extending along the second direction Y. Such arrangement achieves the layout design of partial fan-out lines in the display region (Fanout in AA, FIAA), rather than arranging the fan-out line W1 close to a bottom left frame and/or a bottom right frame of the display panel, which is conducive to achieving a narrow frame of the display panel. Especially, a width of a bottom frame of the display panel may be significantly reduced, which is conducive to achieving full-screen design.

It should be noted that in FIG. 14, the number of the data signal lines DL in the first display region AA1 and the second display region AA2 is merely exemplary, rather than representing the actual number of the data signal lines DL. Similarly, the number of the fan-out lines W1 in the fan-out region FA is merely exemplary, rather than representing the actual number of the fan-out lines W1.

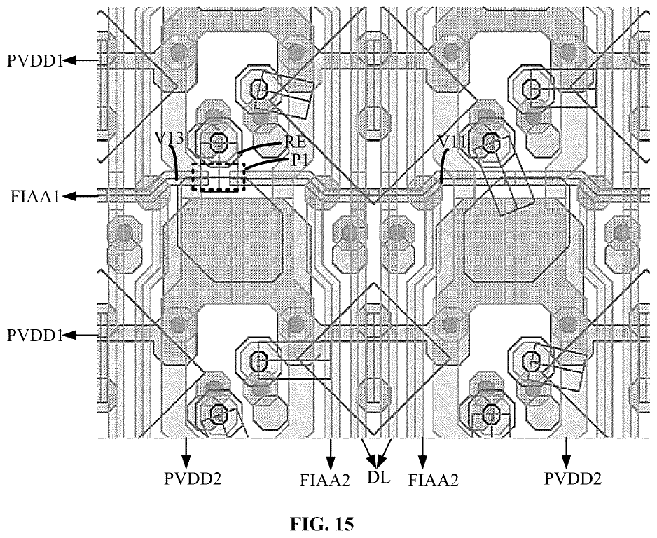

As shown in FIG. 14, the first display region AA1 is arranged in a middle region of the display panel, and the second display region AA2 is arranged on at least one side of the first display region AA1 along the first direction X, that is, on one side or both sides of the first display region AA1 along the first direction X. FIG. 15 is illustrated with an example that the second display region AA2 is arranged on both sides of the first display region AA1.

As shown in FIG. 14, the display panel further includes a pin region PA. The pin region PA is bound to a control chip. In practice, the pin region PA is folded back to a non-light-emitting surface of the display panel to reduce the width of the bottom frame of the display panel.

It should further be noted that, as shown in FIG. 14, an overlapping relationship between the first connection segment V11 and data signal lines DL which the first connection segment V11 passes through along the first direction X does not represent an electrical connection between the first connection segment V11 and the data signal lines DL. Actually, the first connection segment V11 extending along the first direction X may not be electrically connected to the data signal lines DL which the first connection segment V11 passes through. Therefore, the first connection segment V11 extending along the first direction X and the data signal line DL extending along the second direction Y are arranged in different layers.

FIG. 15 shows a schematic diagram of a layout structure of a dashed box U1 in FIG. 14. In one embodiment, the layout structure is formed by stacking the metal layer M3, the metal layer M4, and the metal layer RE. It can be seen that for one data signal line DL in the second display region AA2, the data signal line DL is electrically connected to the first connection segment V11 extending along the first direction X.

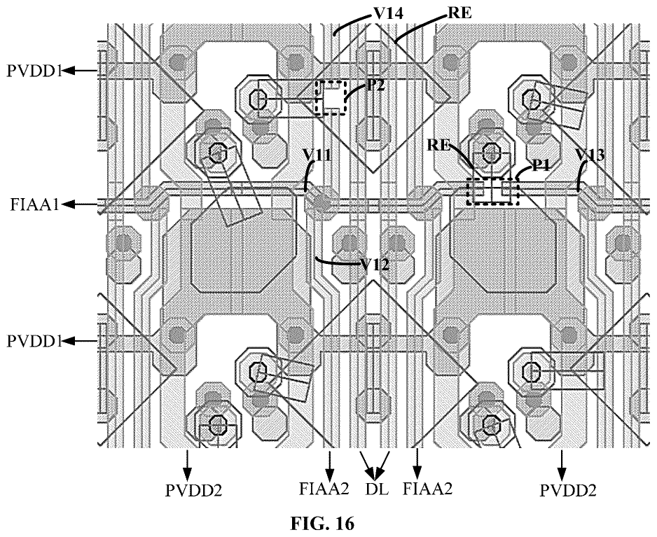

FIG. 16 shows a schematic diagram of a layout structure of a dashed box U2 in FIG. 14. In one embodiment, the layout structure is formed by stacking the metal layer M3, the metal layer M4, and the metal layer RE. It can be seen that the first connection segment V11 extending along the first direction X is electrically connected to the second connection segment V12 extending along the second direction Y, and ultimately is electrically connected to the fan out-line W1 in the fan-out region FA.

Actually, considering the etching uniformity and the reflection effect uniformity of the display panel, as shown in FIGS. 8, 9a and 9b, a first connection line FIAA1 extending along the first direction X is arranged between two adjacent rows of the pixel circuits 20. As shown in FIGS. 15 and 16, for each of at least some first connection lines FIAA1, the first connection line FIAA1 includes the first connection segment V11.

Moreover, as shown in FIGS. 8, 9a and 9b, at least one second connection line FIAA2 extending along the second direction Y is arranged between two adjacent columns of the pixel circuits 20. FIGS. 8, 9a and 9b illustrate a case where two second connection lines FIAA2 extending along the second direction Y are arranged between two adjacent columns of the pixel circuits 20, and as shown in FIGS. 15 and 16, for each of at least some second connection lines FIAA2, the second connection line FIAA2 includes the second connection segment V12.

In an embodiment, as shown in FIGS. 8, 9a and 9b, the first connection line FIAA1 and the first sub-power signal line PVDD1 may be arranged in a same layer and insulated from each other, and the first connection line FIAA1 and the first power signal line PVDD1 are arranged in the metal layer M3. In such case, the first connection segment V11 and the first sub-power signal line PVDD1 may be arranged in a same layer and insulated from each other.

In an embodiment, as shown in FIGS. 8, 9a and 9b, the second connection line FIAA2 and the second sub-power signal line PVDD2 may be arranged in a same layer and insulated from each other, the second connection line FIAA2 and the second sub-power signal line PVDD2 are arranged in the metal layer M4. In such case, the second connection segment and the second sub-power signal line PVDD2 may be arranged in a same layer and insulated from each other.

Moreover, since the data signal line DL, the second power signal line PVDD2, and the second connection line FIAA2 all extend in the second direction Y, the data signal line DL, the second power signal line PVDD2, and the second connection line FIAA2 may be arranged in the same layer and insulated from each other.

The first connection line FIAA1 and the first sub-power signal line PVDD1 are arranged in the same layer and insulated from each other, and the second connection line FIAA2, the second sub-power signal line PVDD2, and the data signal line DL are arranged in the same layer and insulated from each other, and the signal lines extending along the same direction may be arranged in the same metal layer, reducing the occupation of the film, which is conductive to achieving the light and thin display panel.

In other embodiments of the present disclosure, the first connection line FIAA1 and the first sub-power signal line PVDD1 may be arranged in the metal layer M4, and the first connection segment V11 is also arranged in the metal layer M4. The second connection line FIAA2, the second sub-power signal line PVDD2, and the data signal line DL may be arranged in the metal layer M3, and the second connection segment V12 is also arranged in the metal layer M3.

It can be understood that the first connection line FIAA1 including the first connection segment V11 is not completely used to transmit the data signal, only the first connection segment V11 is used to transmit the data signal. Similarly, the second connection line FIAA2 including the second connection segment V12 is not completely used to transmit the data signal, only the second connection segment V12 is used to transmit the data signal. Therefore, as shown in FIGS. 15 and 16, the display panel further includes multiple first auxiliary segments V13 extending along the first direction X and multiple second auxiliary segments V14 extending along the second direction Y. The first auxiliary segments V13 and the first connection segment V11 are arranged in a same layer, and the first auxiliary segments V13 are insulated from the first connection segment V11 and the first sub-power signal line PVDD1. The second auxiliary segments V14 and the second connection segment V12 are arranged in a same layer, and the second auxiliary segments V14 are insulated from the second connection segment V12 and the second sub-power line PVDD2.

That is, the first auxiliary segments V13 in the first connection line FIAA1 are not used to transmit the data signal. The first auxiliary segments V13, the first connection segment V11 and the first sub-power signal line PVDD1 are arranged in a same layer and insulated from each other.

Similarly, the second auxiliary segments V14 in the second connection line FIAA2 are not used to transmit the data signal. The second auxiliary segments V14, the second connection segment V12 and the second sub-power signal line PVDD2 are arranged in a same layer and insulated from each other.

As shown in FIGS. 15 and 16, for the first connection line FIAA1 including the first connection segment V11 and the first auxiliary segment V13, a first gap P1 is defined between the first auxiliary segment V13 and the first connection segment V11 to isolate the first auxiliary segment V13 from the first connection segment V11 and avoid signal crosstalk between the first connection segment V11 for transmitting the data signal and the first auxiliary segment V13 not for transmitting the data signal.

Similarly, as shown in FIGS. 15 and 16, for the second connection line FIAA2 including the second connection segment V12 and the second auxiliary segment V14, a second gap P2 is defined between the second auxiliary segment V14 and the second connection segment V12 to isolate the second auxiliary segment V14 from the second connection segment V12, and avoid signal crosstalk between the second connection segment V12 for transmitting the data signal and the second auxiliary segment V14 not for transmitting the data signal.

As shown in FIGS. 1, 8, and 9c, the light-emitting element 40 includes an anode RE, a light-emitting layer (not shown), and a cathode (not shown) that are arranged in a direction away from the substrate 10. As shown in FIGS. 15 and 16, the anode RE covers the first gap P1 and the second gap P2 in the direction perpendicular to the plane where the substrate 10 is located.

That is, the first gap P1 (i.e. a disconnection position) in the first connection line FIAA1 extending along the first direction X is obstructed by the anode RE of the light-emitting element 40 in the direction perpendicular to the plane where the substrate 10 is located, and the second gap P2 (i.e. a disconnection position) in the second connection line FIAA2 extending along the second direction Y is also obstructed by the anode RE of the light-emitting element 40 in the direction perpendicular to the plane where the substrate 10 is located. The metal may reflect light but not transmit light, and thus the display panel is uniform in appearance and has a relatively uniform reflection effect on the light, to avoid the visual uneven display between the disconnection positions of the display panel and other positions in a dark state and a display state, and improve the display uniformity of the display panel.

It should be noted that in the direction perpendicular to the plane where the substrate 10 is located, the anode RE covers the first gap P1 and the second gap P2, which indicates that an orthographic projection of the first gap P1 and an orthographic projection of the second gap P2 on the plane where the substrate 10 is located are within a range of a forward projection of the anode RE on the plane where the substrate 10 is located.

It can be understood that in addition to the first connection line FIAA1 including the first auxiliary segment V13 not for transmitting the data signal, the first connection line FIAA1 completely not for transmitting the data signal is further provided. Similarly, in addition to the second connection line FIAA2 including the second auxiliary segment V14 not for transmitting the data signal, and the second connection line FIAA2 completely not for transmitting the data signal is further provided. FIGS. 8, 9a and 9b show the first connection line FIAA1 completely not for transmitting the data signal and the second connection line FIAA1 completely not for transmitting the data signal.

As shown in FIGS. 15 and 16, in the direction perpendicular to the plane where the substrate 10 is located, the first connection segment V11 extending along the first direction X may be electrically connected to the second connection segment V12 extending along the second direction Y through a via-hole between the metal layer M3 and the metal layer M4 at an overlapping position of the first connection segment V11 and the second connection segment V12. Similarly, the first auxiliary segment V13 extending along the first direction X may be electrically connected to the second auxiliary segment V14 extending along the second direction Y through a via-hole between the metal layer M3 and the metal layer M4 at an overlapping position of the first auxiliary segment V13 and the second auxiliary segment V14. In one embodiment, as shown in FIGS. 8, 9a and 9b, the first auxiliary segment V13 extending along the first direction X is electrically connected to the second auxiliary segment V14 extending along the second direction Y sequentially through a connection portion E1 arranged in the metal layer M3 and a connection portion E2 arranged in the metal layer M4. The connection portion E1 in the metal layer M3 is electrically connected to the connection portion E2 in the metal layer M4 through the via-hole between the metal layer M3 and the metal layer M4.

As shown in FIGS. 5, 6, 7a, 7f, 8, 9a and 9b, the data signal line DL arranged in the metal layer M4 is electrically connected to the first electrode p21 of the data writing transistor T2 sequentially through the connection portion E3 arranged in the metal layer M4, the connection portion E4 arranged in the metal layer M3, the connection portion E5 arranged in the metal layer M2, and the connection portion E6 arranged in the active layer poly.

As shown in FIGS. 8, 9a, and 9b, the first auxiliary segment V13 extends along the first direction X and is arranged along the second direction Y, and the second auxiliary segment V14 extends along the second direction Y and is arranged along the first direction X. Therefore, the first auxiliary segment V13 and the second auxiliary segment V14 also form the grid structure. In an embodiment, both the first auxiliary segment V13 and the second auxiliary segment V14 are connected to a fixed potential.

For the first auxiliary segment V13, all the first auxiliary segments V13 may be connected to the first power signal line PVDD. The first auxiliary segments V13 are connected in parallel with the first power signal line PVDD, which is conductive to reducing a voltage drop of the first power signal line PVDD, in one embodiment, all the first auxiliary segments V13 may be connected to the second power signal line PVEE. The first auxiliary segments V13 are connected in parallel with the second power signal line PVEE, which is conductive to reducing a voltage drop of the second power signal line PVEE. In one embodiment, some of the first auxiliary segments V13 are connected to the first power signal line PVDD, and some of the first auxiliary segments V13 are connected to the second power signal line PVEE, and the multiple first auxiliary segments V13 are connected in parallel with the first power signal line PVDD and the second power voltage line PVEE, respectively, based on a proportion, reducing both the voltage drop of the first power signal line PVDD and the voltage drop of the second power signal line PVEE. In such way, the display uniformity of the display panel can be improved, and the power consumption can be reduced.

Similarly, for the second auxiliary segment V14, all the second auxiliary segments V14 may be connected to the first power signal line PVDD. The second auxiliary segments V14 are connected in parallel with the first power signal line PVDD, which is conductive to reducing the voltage drop of the first power signal line PVDD. In one embodiment, all the second auxiliary segments V14 may be connected to the second power signal line PVEE. The second auxiliary segments V14 are connected in parallel with the second power signal line PVEE, which is conductive to reducing the voltage drop of the second power signal line PVEE. In one embodiment, some of the second auxiliary segments V14 are connected to the first power signal line PVDD, and some of the second auxiliary segments V14 are connected to the second power signal line PVEE, and the multiple second auxiliary segments V14 are connected in parallel with the first power signal line PVDD and the second power signal line PVEE, respectively, based on a proportion, reducing both the voltage drop of the first power signal line PVDD and the voltage drop of the second power signal line PVEE. In such way, the display uniformity of the display panel can be improved, and the power consumption can be reduced.

It should be noted that the fixed potential is that a potential is constant for a period of time or in an operation state (such as an operation brightness), and the fixed potential may have different potentials for different time periods or in different operation states (such as different operation brightness).

It should be noted that in the present disclosure, a signal line for providing the fixed potential is not limited to the first power signal line PVDD and the second power signal line PVEE, and may be the first reference signal line Vref1, the second reference signal line Vref2 and the like, depending on the situation.

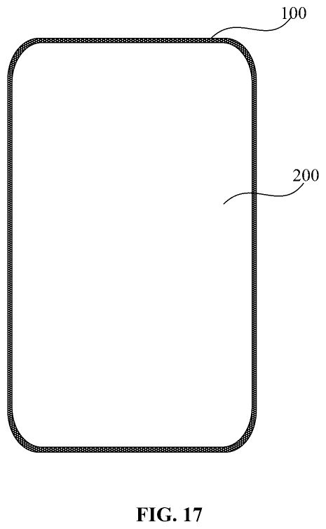

A display device is further provided according to an embodiment of the present disclosure. As shown in FIG. 17, the display device includes the display panel 200 according to any one of the foregoing embodiments. The display panel 200 is described in detail in the foregoing embodiments, which is not repeated herein.

The display device 100 may be an electronic device with a display function, such as a touch screen, a mobile phone, a tablet computer, a laptop, an e-book, or a television.

The embodiments in this specification are described in a progressive way, each of which emphasizes the differences from others, and the same or similar parts among the embodiments can be referred to each other.

Based on the above description of the disclosed embodiments, the features in the embodiments in this specification may be replaced or combined with each other. Various modifications to the embodiments are apparent in the art, and the general principle defined herein can be implemented in other embodiments without departing from the spirit or scope of the present disclosure. Hence, the present disclosure is not limited to the embodiments disclosed herein, but is to conform to the widest scope in accordance with the principles and novel features disclosed herein.

1. A display panel, comprising:
a substrate; and
a pixel circuit and a signal line that are arranged on a side of the substrate, wherein
the pixel circuit comprises a driving transistor, a bias transistor, and a gate initialization transistor, the signal line comprises a bias signal line and a first reference signal line, the bias transistor is electrically connected between at least one of a first electrode and a second electrode of the driving transistor and the bias signal line, and the gate initialization transistor is electrically connected between a gate of the driving transistor and the first reference signal line;
the bias signal line comprises a first sub-bias signal line extending along a first direction and arranged along a second direction, and a second sub-bias signal line extending along the second direction and arranged along the first direction, the first direction intersects with the second direction, and the first sub-bias signal line is electrically connected to the second sub-bias signal line;
the first reference signal line comprises a first sub-reference signal line extending along the first direction and arranged along the second direction, and a second sub-reference signal line extending along the second direction and arranged along the first direction, and the first sub-reference signal line is electrically connected to the second sub-reference signal line; and
the bias signal line and the first reference signal line are insulated from each other.

2. The display panel according to claim 1, wherein the first sub-bias signal line and the second sub-bias signal line are arranged in different layers, the first sub-reference signal line and the second sub-reference signal line are arranged in different layers, and the first sub-bias signal line and the first sub-reference signal line are arranged in a same layer.

3. (canceled)

4. The display panel according to claim 2, wherein
the pixel circuit is arranged in an array along the first direction and the second direction;
the number of rows of the pixel circuit is N10, the number of the first sub-bias signal line is N11, and the number of the first sub-reference signal line is N12, wherein N11≤N10, N12≤N10, and N10, N11, and N12 are positive integers.

5. The display panel according to claim 2, further comprising a light-emitting element, wherein
the light-emitting element comprises an anode, a light-emitting layer, and a cathode that are arranged in a direction away from the substrate;
the pixel circuit further comprises an anode initialization transistor, and the anode initialization transistor is electrically connected to the anode of the light-emitting element;
the signal line further comprises a bias control signal line, and the bias control signal line is electrically connected to a gate of the anode initialization transistor and a gate of the bias transistor;
the bias control signal line extends along the first direction, and the bias control signal line and the first sub-bias signal line are arranged in different layers; and
in a direction perpendicular to a plane where the substrate is located, the first sub-bias signal line at least partially overlaps with the bias control signal line.

6. The display panel according to claim 2, wherein
the pixel circuit further comprises a first light-emitting control transistor and a second light-emitting control transistor, the signal line further comprises a first power signal line and a light-emitting control signal line, and the display panel further comprises a light-emitting element;
the first light-emitting control transistor is electrically connected between the first power signal line and the first electrode of the driving transistor, the second light-emitting control transistor is electrically connected between the second electrode of the driving transistor and the light-emitting element, and the light-emitting control signal line is electrically connected to a gate of the first light-emitting control transistor and a gate of the second light-emitting control transistor;
the light-emitting control signal line extends along the first direction, and the light-emitting control signal line and the first sub-reference signal line are arranged in different layers; and
in a direction perpendicular to a plane where the substrate is located, the first sub-reference signal line at least partially overlaps with the light-emitting control signal line.

7. The display panel according to claim 2, further comprising a first metal layer, an oxide layer, and a second metal layer that are arranged in a direction away from the substrate, wherein
the gate initialization transistor is an oxide thin film transistor, the gate initialization transistor comprises a first channel region, a first bottom gate arranged on a side of the first channel region close to the substrate, and a first top gate arranged on a side of the first channel region away from the substrate, the first channel region is arranged in the oxide layer, the first bottom gate is arranged in the first metal layer, and the first top gate is arranged in the second metal layer; and
the first sub-bias signal line and the first sub-reference signal line are arranged in the second metal layer, and the first sub-bias signal line and the first sub-reference signal line are insulated from the first top gate.

8. The display panel according to claim 2, wherein
the second sub-bias signal line and the second sub-reference signal line are arranged in a same layer;
the pixel circuit is arranged in an array along the first direction and the second direction; and
the number of columns of the pixel circuit is N20, the number of the second sub-bias signal line is N21, and the number of the second sub-reference signal line is N22, wherein N21<N20, N22≤N20, and N20, N21, and N22 are positive integers.

9. (canceled)

10. The display panel according to claim 1, further comprising a light-emitting element, wherein
the light-emitting element comprises an anode, a light-emitting layer, and a cathode that are arranged in a direction away from the substrate;
the pixel circuit further comprises an anode initialization transistor, the signal line further a second reference signal line, the anode initialization transistor is electrically connected between the second reference signal line and the anode of the light-emitting element;
the second reference signal line comprises a third sub-reference signal line extending along the first direction and arranged along the second direction, and a fourth sub-reference signal line extending along the second direction and arranged along the first direction, and the third sub-reference signal line is electrically connected to the fourth sub-reference signal line; and
the bias signal line, the first reference signal line, and the second reference signal line are insulated from each other.

11. The display panel according to claim 10, wherein the first sub-bias signal line and the second sub-bias signal line are arranged in different layers, the first sub-reference signal line and the second sub-reference signal line are arranged in different layers, the third sub-reference signal line and the fourth sub-reference signal line are arranged in different layers, and the second sub-bias signal line, the second sub-reference signal line, and the fourth sub-reference signal line are arranged in a same layer.

12. (canceled)

13. The display panel according to claim 11, wherein
the pixel circuit is arranged in an array along the first direction and the second direction;
the number of columns of the pixel circuit is N20, the number of the second sub-bias signal line is N21, the number of the second sub-reference signal line is N22, and the number of the fourth sub-reference signal line is N23, wherein N21≤N20, N22≤N20, N23≤N20, and N20, N21, N22, and N23 are positive integers.

14. The display panel according to claim 13, wherein N21+N22+N23≤N20.

15. The display panel according to claim 13, wherein
one of the second sub-bias signal line, the second sub-reference signal line, and the fourth sub-reference signal line is arranged corresponding to each column of the pixel circuit;
in four adjacent columns of the pixel circuit, two columns of the pixel circuit correspond to a same one of the second sub-bias signal line, the second sub-reference signal line, and the fourth sub-reference signal line, and the other two columns of the pixel circuit correspond to the other two of the second sub-bias signal line, the second sub-reference signal line, and the fourth sub-reference signal line, respectively;
in the four adjacent columns of the pixel circuit, the two columns of the pixel circuit correspond to the same one of the second sub-bias signal line, the second sub-reference signal line, and the fourth sub-reference signal line are arranged with an intervening column;
the light-emitting element comprises a first color light-emitting element, a second color light-emitting element, and a third color light-emitting element;
in two adjacent columns of the pixel circuit, one column of the pixel circuit is configured to drive the first color light-emitting element, and the other column of the pixel circuit is configured to drive the second color light-emitting element and the third color light-emitting element; and
in the four adjacent columns of the pixel circuit, the two columns of the pixel circuit correspond to the same one of the second sub-bias signal line, the second sub-reference signal line, and the fourth sub-reference signal line are configured to drive the first color light-emitting element.

16. (canceled)

17. The display panel according to claim 15, wherein
in the four adjacent columns of the pixel circuit, the two columns of the pixel circuit correspond to the same one of the second sub-bias signal line, the second sub-reference signal line, and the fourth sub-reference signal line are arranged with an intervening column;
the light-emitting element comprises a first color light-emitting element, a second color light-emitting element, and a third color light-emitting element;
in two adjacent columns of the pixel circuit, one column of the pixel circuit is configured to drive the first color light-emitting element, and the other column of the pixel circuit is configured to drive the second color light-emitting element and the third color light-emitting element; and
in the four adjacent columns of the pixel circuit, the two columns of the pixel circuit correspond to the same one of the second sub-bias signal line, the second sub-reference signal line, and the fourth sub-reference signal line are configured to drive the first color light-emitting element.

18. (canceled)

19. The display panel according to claim 13, wherein one first sub-bias signal line, one first sub-reference signal line, and one third sub-reference signal line are arranged corresponding to each row of the pixel circuit.

20. The display panel according to claim 19, further comprising a plurality of first connection portions arranged in an array along the first direction and the second direction;
wherein the plurality of first connection portions extend along the first direction, the plurality of first connection portions and the first sub-bias signal line are arranged in different layers, and the first sub-bias signal line is electrically connected to the bias transistor through the plurality of first connection portions;
wherein the second sub-bias signal line further comprises a second connection portion extending along the first direction, the second connection portion is electrically connected to the plurality of first connection portions in a same layer, and the second sub-bias signal line is electrically connected to the bias transistor through the second connection portion and the plurality of first connection portions.

21. (canceled)

22. The display panel according to claim 19, further comprising a plurality of third connection portions arranged in an array along the first direction and the second direction;
wherein the plurality of third connection portions extend along the second direction, the plurality of third connection portions and the first sub-reference signal line are arranged in different layers, and the first sub-reference signal line is electrically connected to the gate initialization transistor through the plurality of third connection portions;
wherein the second sub-reference signal line further comprises a fourth connection portion extending along the first direction, the fourth connection portion is electrically connected to the plurality of third connection portions in a same layer, and the second sub-reference signal line is electrically connected to the anode initialization transistor through the fourth connection portion.

23-24. (canceled)

25. The display panel according to claim 10, wherein
the pixel circuit further comprises a first light-emitting control transistor, the signal line further comprises a first power signal line, and the first light-emitting control transistor is electrically connected between the first power signal line and the first electrode of the driving transistor;
the first power signal line comprises a first sub-power signal line extending along the first direction and arranged along the second direction, and a second sub-power signal line extending along the second direction and arranged along the first direction, and the first sub-power signal line is electrically connected to the second sub-power signal line; and
the bias signal line, the first reference signal line, the second reference signal line and the first power signal line are insulated from each other.

26. The display panel according to claim 25, wherein the first sub-bias signal line and the second sub-bias signal line are arranged in different layers, the first sub-reference signal line and the second sub-reference signal line are arranged in different layers, the third sub-reference signal line and the fourth sub-reference signal line are arranged in different layers, and the first sub-power signal line and the second sub-power signal line are arranged in different layers.

27-32. (canceled)

33. The display panel according to claim 26, wherein
the pixel circuit is arranged in an array along the first direction and the second direction, the signal line further comprises a data signal line extending along the second direction, and the pixel circuit arranged in one column is electrically connected to one data signal line;
the display panel further comprises a display region and a non-display region at least partially surrounding the display region, the non-display region comprises a fan-out region arranged on a side of the display region along the second direction, and the fan-out region comprises a plurality of fan-out lines;
the display region comprises a first display region and a second display region arranged on at least one side of the first display region along the first direction, each of the first display region and the second display region comprises a plurality of data signal lines, the plurality of data signal lines are electrically connected to the plurality of fan-out lines, and the plurality of data signal lines in the second display region are electrically connected to the plurality of fan-out lines through a connection line; and
the connection line is arranged in the display region, the connection line comprises a first connection segment extending along the first direction and a second connection segment extending along the second direction, the second connection segment is electrically connected to the plurality of fan-out lines, and the first connection segment is electrically connected to the plurality of data signal lines in the second display region.

34-37. (canceled)

38. A display device, comprising a display panel, wherein the display device comprises:
a substrate; and
a pixel circuit and a signal line that are arranged on a side of the substrate, wherein
the pixel circuit comprises a driving transistor, a bias transistor, and a gate initialization transistor, the signal line comprises a bias signal line and a first reference signal line, the bias transistor is electrically connected between at least one of a first electrode and a second electrode of the driving transistor and the bias signal line, and the gate initialization transistor is electrically connected between a gate of the driving transistor and the first reference signal line;
the bias signal line comprises a first sub-bias signal line extending along a first direction and arranged along a second direction, and a second sub-bias signal line extending along the second direction and arranged along the first direction, the first direction intersects with the second direction, and the first sub-bias signal line is electrically connected to the second sub-bias signal line;
the first reference signal line comprises a first sub-reference signal line extending along the first direction and arranged along the second direction, and a second sub-reference signal line extending along the second direction and arranged along the first direction, and the first sub-reference signal line is electrically connected to the second sub-reference signal line; and
the bias signal line and the first reference signal line are insulated from each other.
